(19) United States
(12) Patent Application Publication
(10) Pub. No.: US 2012/0056255 A1
(43) Pub. Date: Mar. 8, 2012

(54) Semiconductor device and method of fabricating the same

(75) Inventor: Mitsunari Sukekawa, Tokyo (JP)

(73) Assignee: ELPIDA MEMORY, INC., Tokyo (JP)

(21) Appl. No.: 13/137,615

(22) Filed: Aug. 30, 2011

(30) Foreign Application Priority Data
Sep. 3, 2010 (JP) P2010-198200

(51) Int. Cl. H01L 27/108; H01L 29/78

(52) U.S. Cl. 257/296; 257/329; 257/E27.084; 257/E29.262

(57) ABSTRACT

A semiconductor device includes a device formation region including a plurality of unit regions arranged in series to each other, each unit region comprising first and second active regions alternately arranged in series to each other. The first active region extends in a first direction. The second active region extends obliquely to the first direction. A plurality of first semiconductor pillars is arranged in the first direction and in each of the first active regions. A second semiconductor pillar is in each of the second active regions. A first bit line includes a first diffusion layer in the device formation region. The first diffusion layer extends under the plurality of first semiconductor pillars and the second semiconductor pillar. The first bit line connects the plurality of first semiconductor pillars and the second semiconductor pillar. A second bit line is electrically connected to the second semiconductor pillar.

### BACKGROUND OF THE INVENTION

1. Field of the Invention

The present invention relates to a semiconductor device and a method of fabricating the same.

Priority is claimed on Japanese Patent Application No. 2010-198200, filed Sep. 3, 2010, the content of which is incorporated herein by reference.

2. Description of the Related Art

In recent years, with the downscaling of semiconductor devices, a plane region occupied by a semiconductor device has been reduced to reduce a region (or active region) where a transistor is formed. In a planar transistor, with a reduction in area of the active region, a channel length and a channel width are reduced to cause problems such as a short channel effect (SCE).

Accordingly, a semiconductor device having a vertical transistor in which a desired channel length and channel width may be ensured even in a downscaled region has been proposed instead of the planar transistor. These are disclosed in Japanese Patent Laid-Open No. 2008-311641 and Japanese Patent Laid-Open No. 2009-10366.

Unlike the planar transistor, the vertical transistor includes a semiconductor pillar formed in a direction vertical to a main surface of a semiconductor substrate, and a channel is formed in a direction vertical to the corresponding main surface in the semiconductor pillar in an on state. Accordingly, the vertical transistor may be effectively applied to a semiconductor memory device that is representative as a micro-dynamic random access memory (micro-DRAM), as compared with the planar transistor.

In general, when a vertical transistor having a semiconductor pillar is used as a cell transistor of a semiconductor memory device, one of diffusion layers functioning as a source or drain is connected to a bit line, while the other thereof is connected to a memory device (e.g., a capacitor of a DRAM). Normally, since the memory device, such as the capacitor, is disposed on the cell transistor, the memory device is connected to an upper portion of the semiconductor pillar, while the bit line is connected to a lower portion thereof.

Since a semiconductor substrate is disposed under the semiconductor pillar, it is necessary to bury the bit line within the semiconductor substrate to form the bit line under the semiconductor pillar. Although a buried bit line may be formed using a diffusion layer, an interconnection having the diffusion layer has an increased resistance and may be a serious obstacle to high-speed operations.

### SUMMARY

In one embodiment, a semiconductor device may include, but is not limited to, a device formation region including a plurality of unit regions arranged in series to each other, each unit region including first and second active regions alternately arranged in series to each other, the first active region extending in a first direction, and the second active region extending obliquely to the first direction; a plurality of first semiconductor pillars arranged in the first direction and in each of the first active regions; a second semiconductor pillar in each of the second active regions; a first bit line including a first diffusion layer in the device formation region, the first diffusion layer extending under the plurality of first semiconductor pillars and the second semiconductor pillar, the first bit line connecting the plurality of first semiconductor pillars and the second semiconductor pillar; and a second bit line electrically connected to the second semiconductor pillar.

In another embodiment, a semiconductor device may include, but is not limited to, a semiconductor substrate including a plurality of device formation regions defined by a plurality of device isolation grooves, each device formation region including a plurality of unit regions, each unit region including first and second active regions alternately arranged in series to each other, the first active region extending in the first direction, and the second active region extending obliquely to the first direction; a plurality of first semiconductor pillars arranged in the first direction and in each of the first active regions;

a plurality of second semiconductor pillars, each of which is arranged in each of the second active regions; a plurality of first bit lines including first diffusion layers in the device formation regions, the first diffusion layers extending under the plurality of first semiconductor pillars and the second semiconductor pillars, each of the first bit lines connecting the plurality of first semiconductor pillars and the second semiconductor pillars in each of the device formation regions; a plurality of second diffusion regions on tops of the plurality of first semiconductor pillars and the second semiconductor pillars; a plurality of second bit lines electrically connected to the second semiconductor pillars, each of the second bit lines being electrically connected through the plurality of second diffusion regions to the second semiconductor pillars; a plurality of second bit lines electrically connected to the second semiconductor pillars; a plurality of first insulating layers disposed over the plurality of first semiconductor pillars, the plurality of first insulating layers insulating the second bit lines from the plurality of first semiconductor pillars; a plurality of second insulating films on side surfaces of the plurality of first semiconductor pillars and a side surface of the second semiconductor pillar; and a plurality of word lines on the plurality of second insulating films.

In still another embodiment, a semiconductor device may include, but is not limited to, a device formation region including plural pairs of first and second active regions alternately arranged in series to each other; a plurality of first semiconductor pillars arranged in the first direction and in each of the first active regions; a second semiconductor pillar in each of the second active regions; a first bit line including a first diffusion layer in the device formation region, the first diffusion layer extending under the plurality of first semiconductor pillars and the second semiconductor pillar, the first bit line connecting the plurality of first semiconductor pillars and the second semiconductor pillar; a second bit line electrically connected to the second semiconductor pillar; and a plurality of first insulating layers disposed over the plurality of first semiconductor pillars, the plurality of first insulating layers insulating the second bit line from the plurality of first semiconductor pillars.

In yet another embodiment, a method of forming a semiconductor device may further include, but is not limited to, forming device isolation grooves in a semiconductor substrate by using a first insulating mask, the device isolation grooves defining device formation regions, each of the device formation regions including a plurality of unit regions arranged in series to each other, each unit region including first and second active regions alternately arranged in series to each other, the first active region extending in a first direction, and the second active region extending obliquely to the first direction; introducing first impurity ions into the semiconductor substrate under the device isolation grooves to form first impurity diffusion regions; making the device isolation grooves deeper to divide each of the first impurity diffusion regions into a pair of two separate impurity diffusion regions performing as a first bit line; forming first insulating films which fill the device isolation grooves which insulate the pair of two separate impurity diffusion regions from each other; introducing second impurity ions into upper regions of the device formation regions by using the first insulating mask; forming word line formation grooves in the semiconductor substrate to define, with the device isolation grooves, a plurality of first semiconductor pillars in each of the first active regions and a second semiconductor pillar in each of the second active regions, the word line formation grooves extending in a second direction, the word line formation grooves being distanced in the first direction; forming second insulating films on the word line formation grooves; forming word lines on the second insulating films and in the word line formation grooves; forming a third insulating film which fills the word line formation grooves and covers the word lines; removing the third insulating film over the second semiconductor pillars to expose the tops of the second semiconductor pillars; and forming second bit lines on the third insulating film and on the tops of the second semiconductor pillars, the second bit lines extending in the first direction, the second bit lines being lower in resistivity than the first bit lines.

In some cases, the method may further include, but is not limited to, forming a fourth insulating film over the second bit lines; forming a fifth insulating film over the fourth insulating film; forming a second mask of stripe portions covering the second semiconductor pillars, the stripe portions extending in the second direction, the stripe portions being distanced in the first direction; selectively removing the third and fifth insulating films by using the second mask to form subsidiary isolation insulating films over the second semiconductor pillars and to expose the tops of the first semiconductor pillars, subsidiary isolation insulating films extending in the second direction; forming a contact plug conductive film entirely; etching back the contact plug conductive film so that the top of the contact plug conductive film is lower in level than the tops of the first semiconductor pillars; forming a multi-layered insulating structure over the contact plug conductive film and the fourth insulating film and over the subsidiary isolation insulating films, the multi-layered insulating structure including insulating films which are different in etching rate from each other; etching the multi-layered insulating structure at etching selectivity between two adjacent ones of the multi-layered insulating structure, to form a third mask; and etching the contact plug conductive film by using the third mask to form contact plugs on the first semiconductor pillars.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a fragmentary plan view of a semiconductor device in accordance with an embodiment of the present invention;

FIG. 1B is a fragmentary cross sectional elevation view of the semiconductor device, taken along an A-A′ line of FIG. 1A;

FIG. 1C is a fragmentary cross sectional elevation view of the semiconductor device, taken along a B-B′ line of FIG. 1A;

FIG. 2 is a circuit diagram illustrating a DRAM memory cell region in accordance with an embodiment of the present invention;

FIG. 3A is a fragmentary plan view of a step involved in a method of forming the semiconductor device of FIGS. 1A, 1B and 1C;

FIG. 3B is a fragmentary plan view of the step, taken along B-B′ line of FIG. 3A;

FIG. 4A is a fragmentary plan view of a step, subsequent to the step of FIGS. 3A and 3B, involved in the method of forming the semiconductor device of FIGS. 1A, 1B and 1C;

FIG. 4B is a fragmentary plan view of the step, taken along B-B′ line of FIG. 4A;

FIG. 5A is a fragmentary plan view of a step, subsequent to the step of FIGS. 4A and 4B, involved in the method of forming the semiconductor device of FIGS. 1A, 1B and 1C;

FIG. 5B is a fragmentary plan view of the step, taken along A-A′ line of FIG. 5A;

FIG. 5C is a fragmentary plan view of patterns in the step of FIG. 5A;

FIG. 6A is a fragmentary plan view of a step, subsequent to the step of FIGS. 5A and 5B, involved in the method of forming the semiconductor device of FIGS. 1A, 1B and 1C;

FIG. 6B is a fragmentary plan view of the step, taken along A-A′ line of FIG. 6A;

FIG. 7A is a fragmentary plan view of a step, subsequent to the step of FIGS. 6A and 6B, involved in the method of forming the semiconductor device of FIGS, 1A, 1B and 1C;

FIG. 7B is a fragmentary plan view of the step, taken along A-A′ line of FIG. 7A;

FIG. 8A is a fragmentary plan view of a step, subsequent to the step of FIGS. 7A and 7B, involved in the method of forming the semiconductor device of FIGS. 1A, 1B and 1C;

FIG. 8B is a fragmentary plan view of the step, taken along C-C′ line of FIG. 8A;

FIG. 9A is a fragmentary plan view of a step, subsequent to the step of FIGS. 8A and 8B, involved in the method of forming the semiconductor device of FIGS. 1A, 1B and 1C;

FIG. 9B is a fragmentary plan view of the step, taken along C-C′ line of FIG. 9A;

FIG. 10A is a fragmentary plan view of a step, subsequent to the step of FIGS. 9A and 9B, involved in the method of forming the semiconductor device of FIGS. 1A, 1B and 1C;

FIG. 10B is a fragmentary plan view of the step, taken along B-B′ line of FIG. 10A;

FIG. 11A is a fragmentary plan view of a step, subsequent to the step of FIGS. 10A and 10B, involved in the method of forming the semiconductor device of FIGS. 1A, 1B and 1C;

FIG. 11B is a fragmentary plan view of the step, taken along B-B′ line of FIG. 11A;

FIG. 12A is a fragmentary plan view of a step, subsequent to the step of FIGS. 11A and 11B, involved in the method of forming the semiconductor device of FIGS. 1A, 1B and 1C;

FIG. 12B is a fragmentary plan view of the step, taken along A-A′ line of FIG. 12A;

FIG. 12C is a fragmentary plan view of the step, subsequent to the step of FIG. 12B, taken along A-A′ line of FIG. 12A;

FIG. 12D is a fragmentary plan view of the step, subsequent to the step of FIG. 12C, taken along A-A′ line of FIG. 12A;

FIG. 13A is a fragmentary plan view of a step, subsequent to the step of FIG. 12D, involved in the method of forming the semiconductor device of FIGS. 1A, 1B and 1C;

FIG. 13B is a fragmentary plan view of the step, taken along A-A′ line of FIG. 13A;

FIG. 13C is a fragmentary plan view of the step, subsequent to the step of FIG. 13B, taken along A-A′ line of FIG. 13A;

FIG. 14A is a fragmentary plan view of a step, subsequent to the step of FIG. 13C, involved in the method of forming the semiconductor device of FIGS. 1A, 1B and 1C;

FIG. 14B is a fragmentary plan view of the step, taken along A-A′ line of FIG. 14A;

FIG. 14C is a fragmentary plan view of the step, subsequent to the step of FIG. 14B, taken along A-A′ line of FIG. 14A;

FIG. 15A is a fragmentary plan view of a step, subsequent to the step of FIG. 14C, involved in the method of forming the semiconductor device of FIGS. 1A, 1B and 1C;

FIG. 15B is a fragmentary plan view of the step, taken along A-A′ line of FIG. 15A;

FIG. 16A is a fragmentary plan view of a step, subsequent to the step of FIGS. 15A and 15B, involved in the method of forming the semiconductor device of FIGS. 1A, 1B and 1C;

FIG. 16B is a fragmentary plan view of the step, taken along A-A′ line of FIG. 16A;

FIG. 17A is a fragmentary plan view of a step, subsequent to the step of FIGS. 16A and 16B, involved in the method of forming the semiconductor device of FIGS. 1A, 1B and 1C; and

FIG. 17B is a fragmentary plan view of the step, taken along A-A′ line of FIG. 17A.

### DETAILED DESCRIPTION OF THE PREFERRED EMBODIMENTS

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a semiconductor device may include, but is not limited to, a device formation region including a plurality of unit regions arranged in series to each other, each unit region including first and second active regions alternately arranged in series to each other, the first active region extending in a first direction, and the second active region extending obliquely to the first direction; a plurality of first semiconductor pillars arranged in the first direction and in each of the first active regions; a second semiconductor pillar in each of the second active regions; a first bit line including a first diffusion layer in the device formation region, the first diffusion layer extending under the plurality of first semiconductor pillars and the second semiconductor pillar, the first bit line connecting the plurality of first semiconductor pillars and the second semiconductor pillar; and a second bit line electrically connected to the second semiconductor pillar.

In some cases, the semiconductor device may include, but is not limited to, a plurality of first insulating layers disposed over the plurality of first semiconductor pillars, the plurality of first insulating layers insulating the second bit line from the plurality of first semiconductor pillars.

In some cases, the semiconductor device may include, but is not limited to, a plurality of second diffusion regions on tops of the plurality of first semiconductor pillars and the second semiconductor pillar. The second bit line is electrically connected through the second diffusion region to the second semiconductor pillar.

In some cases, the second bit line is in contact with the second diffusion region disposed on the top of the second semiconductor pillar.

In some cases, the second bit line extends in the first direction.

In some cases, the semiconductor device may include, but is not limited to, a plurality of second insulating films on side surfaces of the plurality of first semiconductor pillars and a side surface of the second semiconductor pillar; and a plurality of word lines on the plurality of second insulating films.

In some cases, the plurality of word lines extends in a second direction substantially perpendicular to the first direction.

In some cases, the second bit line is lower in resistivity than the first bit line.

In some cases, the first bit line may include, but is not limited to, a pair of first and second bit line portions which are disposed separately in the second direction.

In some cases, each of the word lines may include, but is not limited to, a pair of first and second word line portions which are disposed separately in the first direction.

In some cases, the first bit line may include, but is not limited to, a metal layer.

In some cases, the semiconductor device may include, but is not limited to, a plurality of contact plugs electrically connected to the plurality of second diffusion regions; and a plurality of capacitors electrically connected to the plurality of contact plugs.

In some cases, the device formation region is symmetrical with reference to a center axis which extends in the first direction, the center axis runs on center points of the second active regions.

In another embodiment, a semiconductor device may include, but is not limited to, a semiconductor substrate including a plurality of device formation regions defined by a plurality of device isolation grooves, each device formation region including a plurality of unit regions, each unit region including first and second active regions alternately arranged in series to each other, the first active region extending in the first direction, and the second active region extending obliquely to the first direction; a plurality of first semiconductor pillars arranged in the first direction and in each of the first active regions; a plurality of second semiconductor pillars, each of which is arranged in each of the second active regions; a plurality of first bit lines including first diffusion layers in the device formation regions, the first diffusion layers extending under the plurality of first semiconductor pillars and the second semiconductor pillars, each of the first bit lines connecting the plurality of first semiconductor pillars and the second semiconductor pillars in each of the device formation regions; a plurality of second diffusion regions on tops of the plurality of first semiconductor pillars and the second semiconductor pillars; a plurality of second bit lines electrically connected to the second semiconductor pillars, each of the second bit lines being electrically connected through the plurality of second diffusion regions to the second semiconductor pillars; a plurality of second bit lines electrically connected to the second semiconductor pillars; a plurality of first insulating layers disposed over the plurality of first semiconductor pillars, the plurality of first insulating layers insulating the second bit lines from the plurality of first semiconductor pillars; a plurality of second insulating films on side surfaces of the plurality of first semiconductor pillars and a side surface of the second semiconductor pillar; and a plurality of word lines on the plurality of second insulating films.

In some cases, the first bit line may include, but is not limited to, a pair of first and second bit line portions which are disposed separately in the second direction, and each of the word lines may include, but is not limited to, a pair of first and second word line portions which are disposed separately in the first direction.

In some cases, the semiconductor device may include, but is not limited to, a plurality of contact plugs electrically connected to the plurality of second diffusion regions; and a plurality of capacitors electrically connected to the plurality of contact plugs.

In still another embodiment, a semiconductor device may include, but is not limited to, a device formation region including plural pairs of first and second active regions alternately arranged in series to each other; a plurality of first semiconductor pillars arranged in the first direction and in each of the first active regions; a second semiconductor pillar in each of the second active regions; a first bit line including a first diffusion layer in the device formation region, the first diffusion layer extending under the plurality of first semiconductor pillars and the second semiconductor pillar, the first bit line connecting the plurality of first semiconductor pillars and the second semiconductor pillar; a second bit line electrically connected to the second semiconductor pillar; and a plurality of first insulating layers disposed over the plurality of first semiconductor pillars, the plurality of first insulating layers insulating the second bit line from the plurality of first semiconductor pillars.

In some cases, the first active region extends in the first direction and the second active region extends obliquely to the first direction.

In some cases, the semiconductor device may further include, but is not limited to, a plurality of second diffusion regions on tops of the plurality of first semiconductor pillars and the second semiconductor pillar. The second bit line is electrically connected through the second diffusion region to the second semiconductor pillar.

In some cases, the semiconductor device may further include, but is not limited to, a plurality of second insulating films on side surfaces of the plurality of first semiconductor pillars and a side surface of the second semiconductor pillar; and a plurality of word lines on the plurality of second insulating films. The first bit line may include, but is not limited to, a pair of first and second bit line portions which are disposed separately in a second direction substantially perpendicular to the first direction, and each of the word lines may include, but is not limited to, a pair of fast and second word line portions which are disposed separately in the first direction.

In yet another embodiment, a method of forming a semiconductor device may further include, but is not limited to, forming device isolation grooves in a semiconductor substrate by using a first insulating mask, the device isolation grooves defining device formation regions, each of the device formation regions including a plurality of unit regions arranged in series to each other, each unit region including first and second active regions alternately arranged in series to each other, the first active region extending in a first direction, and the second active region extending obliquely to the first direction; introducing first impurity ions into the semiconductor substrate under the device isolation grooves to form first impurity diffusion regions; making the device isolation grooves deeper to divide each of the first impurity diffusion regions into a pair of two separate impurity diffusion regions performing as a first bit line; forming first insulating films which fill the device isolation grooves which insulate the pair of two separate impurity diffusion regions from each other; introducing second impurity ions into upper regions of the device formation regions by using the first insulating mask; forming word line formation grooves in the semiconductor substrate to define, with the device isolation grooves, a plurality of first semiconductor pillars in each of the first active regions and a second semiconductor pillar in each of the second active regions, the word line formation grooves extending in a second direction, the word line formation grooves being distanced in the first direction; forming second insulating films on the word line formation grooves; forming word lines on the second insulating films and in the word line formation grooves; forming a third insulating film which fills the word line formation grooves and covers the word lines; removing the third insulating film over the second semiconductor pillars to expose the tops of the second semiconductor pillars; and forming second bit lines on the third insulating film and on the tops of the second semiconductor pillars, the second bit lines extending in the first direction, the second bit lines being lower in resistivity than the first bit lines.

In some cases, the method may further include, but is not limited to, forming a fourth insulating film over the second bit lines; forming a fifth insulating film over the fourth insulating film; forming a second mask of stripe portions covering the second semiconductor pillars, the stripe portions extending in the second direction, the stripe portions being distanced in the first direction; selectively removing the third and fifth insulating films by using the second mask to form subsidiary isolation insulating films over the second semiconductor pillars and to expose the tops of the first semiconductor pillars, subsidiary isolation insulating films extending in the second direction; forming a contact plug conductive film entirely; etching back the contact plug conductive film so that the top of the contact plug conductive film is lower in level than the tops of the first semiconductor pillars; forming a multi-layered insulating structure over the contact plug conductive film and the fourth insulating film and over the subsidiary isolation insulating films, the multi-layered insulating structure including insulating films which are different in etching rate from each other; etching the multi-layered insulating structure at etching selectivity between two adjacent ones of the multi-layered insulating structure, to form a third mask; and etching the contact plug conductive film by using the third mask to form contact plugs on the first semiconductor pillars.

In some cases, the number of the insulating films of the multi-layered insulating structure is given by n−1, where n is the number of the first semiconductor pillars.

In some cases, forming the first bit lines may include, but is not limited to, diffusing the first impurity ions from the bottom regions of the device isolation grooves into regions under the device formation regions; and making the device isolation grooves deeper before the first insulating films are formed in the device isolation grooves to form device isolation regions and to form plural pairs of first bit line portions which are distanced from each other in the second direction.

In some cases, the method may further include, but is not limited to, introducing a second impurity into the upper regions of the second semiconductor pillars after removing the third insulating film over the second semiconductor pillars.

In some cases, the multi-layered insulating structure may include, but is not limited to, an alternating lamination of silicon oxide films and silicon nitride films.

In some cases, the method may further include, but is not limited to, forming capacitors connected to the contact plugs.

### (Semiconductor Device)

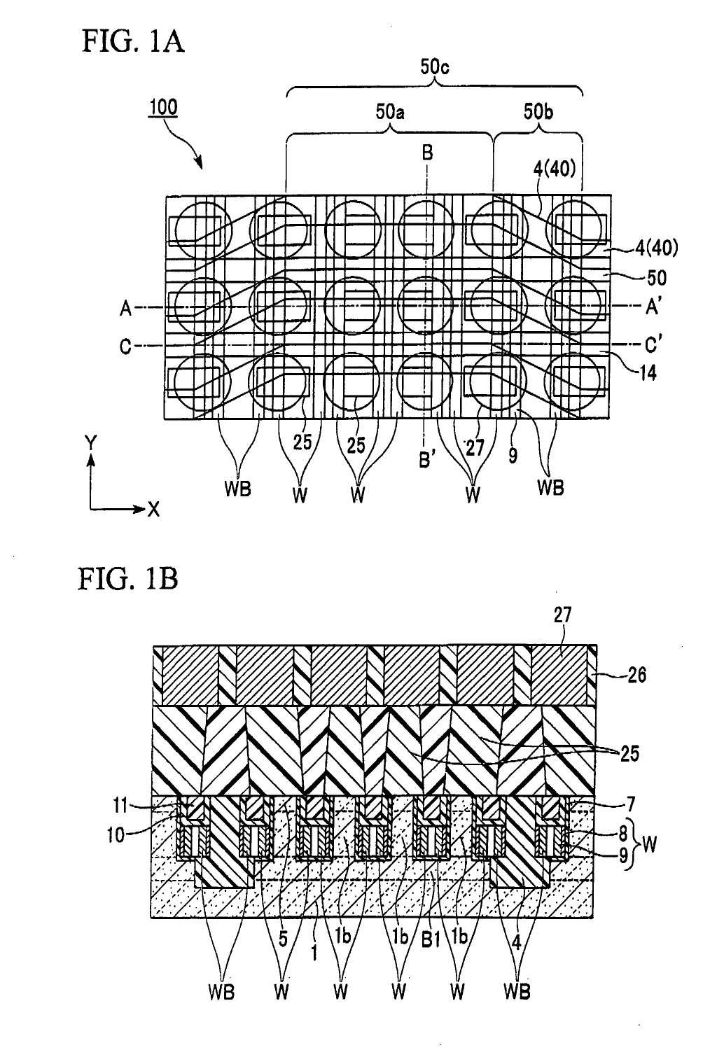

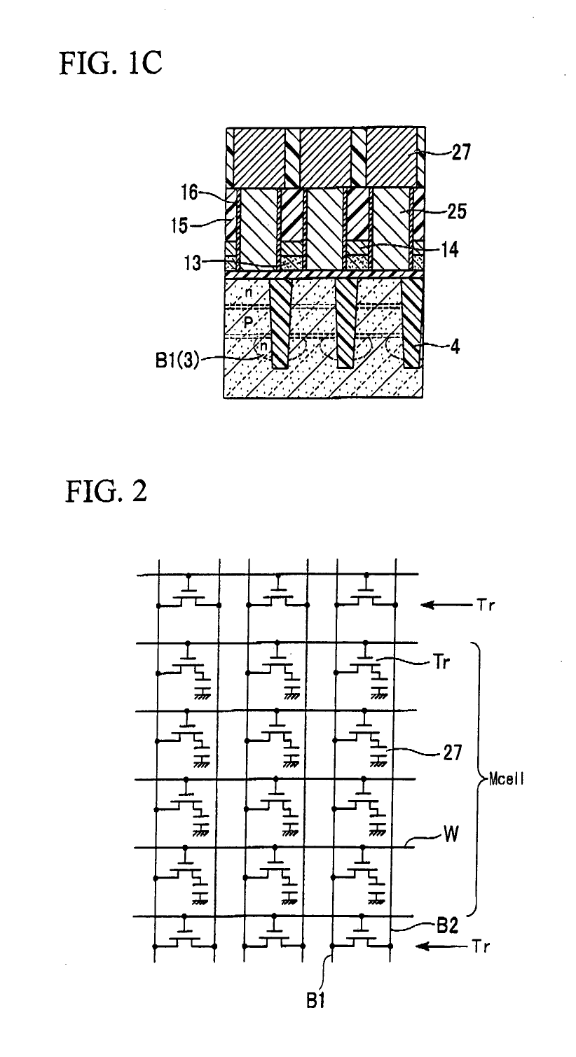

A structure of a semiconductor memory device (DRAM), which is an example of a semiconductor device according to the present invention, will now be described with reference to FIGS. 1A through 1C.

FIG. 1A is a plane layout of a semiconductor device 100 according to the present invention, FIG. 1B is a cross-sectional view taken along line A-A′ of the semiconductor device 100 shown in FIG. 1A, and FIG. 1C is a cross-sectional view taken along line B-B′ of the semiconductor device 100 shown in FIG. 1A.

FIG. 2 is a circuit diagram of an example of a memory cell unit of the semiconductor device 100 shown in FIGS. 1A through 1C.

The semiconductor device 100 may finally function as a DRAM, and each memory cell includes a MOS transistor Tr having a source or drain region (or impurity diffusion region or first bit line) B1, a drain or source region (or upper impurity diffusion region) 5, and gate electrodes W (8 and 9), and a capacitor 27.

The semiconductor device 100 includes a plurality of device isolation groove units (or first groove units), a plurality of device isolation regions (or shallow trench isolation (STI) regions) 40, and a plurality of device formation regions 50. The plurality of first groove units are formed by digging a semiconductor substrate 1 and generally extend in an X direction (or first direction). The device isolation regions 40 are formed by filling the first groove units with a device isolation insulating film (or first insulating film) 4. The plurality of device formation regions 50 are formed between adjacent device isolation regions 40.

The semiconductor substrate 1 is a substrate containing impurities with a predetermined concentration, for example, a single-crystalline p-type silicon substrate. Within a surface of the semiconductor substrate 1, the device isolation regions 40 are called STI regions, while the device formation regions 50 are active regions electrically insulated from one another by the device isolation regions 40. As shown in FIG. 1A, each of the device formation regions 50 includes a combination of a horizontal active region 50a extending in an X direction and an inclined active region 50b inclined with respect to the X direction, as a unit active region 50c. In each of the device formation regions 50, adjacent unit active regions 50c have vertically inverted shapes in a Y direction orthogonal to the X direction and are repetitively connected in the X direction. Accordingly, in each of the device isolation formation regions 50, the horizontal active regions 50a are disposed opposite each other at predetermined intervals in the X direction across a line (corresponding to line A-A′) connecting central points of the inclined active regions 50b. Here, the device formation region 50 and the device isolation region 40 adjacent to the device formation region 50 on the same plane are called a snake pattern.

As shown in FIG. 1B, a plurality of semiconductor pillars 1b are arranged in the horizontal active region 50a along the X direction (or first direction) and installed on a main surface of the semiconductor substrate 1. The present embodiment illustrates four semiconductor pillars lb installed in a row. Since the device formation region 50 is provided as the snake pattern, in the cross-sectional view shown in FIG. 1B, device isolation insulating films 4 constituting the device isolation regions 40 are disposed on both sides of the horizontal active region 50a in which the four semiconductor pillars 1b are installed in a row. Also, a buried bit line (or first bit line) B1 is disposed under the semiconductor pillar 1b according to a plane shape of the device formation region 50. As shown in FIG. 1C, the buried bit line B1 includes an impurity diffusion layer 3 having one end contacting the device isolation insulating film 4. Although two buried bit lines B1 are disposed in one device formation region 50 and in contact with two device isolation insulating films 4 vertically disposed in the Y direction from a plan view, the two buried bit lines B1 function as one buried bit line B1. Each of the two buried bit lines B1 has a snake pattern. The buried bit line B1 is connected to a second bit line having a low resistance installed in the surface of the semiconductor substrate 1 through the semiconductor pillar installed in the inclined active region 50b shown in FIG. 1A. While the first bit line includes a snake pattern, the second bit line includes a straight pattern extending in the X direction. In the present embodiment, the buried bit line (or first bit line) B1 is shared between MOS transistors (or vertical transistors) Tr installed in one device formation region 50 and functions as a source region (or impurity diffusion region).

A groove unit (or second groove unit) is formed in a shallower position than the buried bit line (or first bit line) B1 formed in the semiconductor substrate 1, and extends in the Y direction (or second direction) orthogonal to the X direction (or first direction). The semiconductor pillar 1b has lateral surfaces parallel in the Y direction (or second direction) of the semiconductor pillar 1b due to the groove unit (or second groove unit). A pair of buried word lines W are formed on sidewalls of the groove unit, that is, on the two lateral surfaces of the semiconductor pillar lb parallel in the Y direction (or second direction), and function as gate electrodes using a gate insulating film 7. The buried word lines W (8 and 9) are extended in the Y direction (or second direction) and simultaneously, have top ends disposed in a lower position than opening ends of the second groove unit, that is, the surface of the semiconductor substrate 1.

The vertical transistor Tr may have a double gate structure in which a pair of buried word lines (or gate electrodes) W are disposed opposite both lateral surfaces of the semiconductor pillar 1b through the gate insulating film 7. Accordingly, in the present embodiment, two lateral surfaces of the semiconductor pillar 1b constituting the vertical transistor, which face each other in the Y direction, are surrounded by the device isolation insulating film 4, while two lateral surfaces of the semiconductor pillar 1b, which face each other in the X direction, are surrounded by the buried word line W through the gate insulating film 7. Furthermore, four buried gate electrodes W for semiconductor pillars formed in the horizontal active region 50a function as gate electrodes of switching transistors configured to form an electrical conduction path between the buried bit line B1 and the upper impurity diffusion region 5 connected to the capacitor 27. Meanwhile, one buried gate electrode WB for a semiconductor pillar formed in the inclined active region 50b functions as a gate electrode of a switching transistor configured to form an electrical conduction path between the buried bit line B1 and a second bit line installed on the surface of the semiconductor substrate 1.

An upper impurity diffusion layer 5 is formed in an upper portion of the semiconductor pillar 1b by diffusing impurities. Also, insulating films (or third insulating films) 10 and 11 are buried in the groove unit required for forming word lines.

As shown in FIG. 1A, the semiconductor device 100 includes the horizontal active region 50a, which has four semiconductor pillars and extends in the X direction, and the inclined active region 50b having one semiconductor pillar, and the horizontal active region 50a and the inclined active region 50b constitute the unit active region 50c. The semiconductor pillar installed in the inclined active region 50b constitutes a switching transistor and functions to form an electrical conduction path between the buried bit line B1 and the second bit line B2 electrically connected to the upper impurity diffusion region 5. While the present embodiment illustrates four semiconductor pillars disposed in the horizontal active region 50a, the number of the semiconductor pillars is not limited to four.

The semiconductor device 100 includes a plurality of capacitors 27, each capacitor 27 connected to the upper impurity diffusion layers 5 of the corresponding one of vertical transistors Tr through a contact plug 25 in the horizontal active region 50a. Each of the capacitors 27 includes a lower electrode film, a capacitor insulating film, and an upper electrode film stacked sequentially.

However, the capacitor 27 may have structures other than illustrated in the drawings and is not limited to the above-described structure.

In the semiconductor device 100, the above-described vertical transistor Tr and the capacitor 27 constitute one memory cell. Also, a plurality of memory cells are arranged in a matrix shape in the first and second directions (or X and Y directions) within a surface of the device formation region 50.

While a plurality of memory cells are substantially arranged in the device formation region 50, since it is difficult to illustrate all the memory cells in the semiconductor device 1 of FIG. 1, only a reduced number of memory cells are schematically shown in the device formation region 50 for brevity.

As described above, while a conventional bit line using an impurity diffusion layer has high resistance and hinders high-speed operations, the present invention further includes the second bit line B2, which is vertically connected in parallel to the bit line (or first bit line) B1 using an impurity diffusion layer and has a lower resistance than the bit line (or first bit line) B1. Thus, the resistance of the bit line may be reduced to enable high-speed operations.

Hereinafter, an operation of a memory cell unit of the semiconductor device 100 shown in FIGS. 1A through 1C will be described with reference to FIG. 2, which is a circuit diagram of the memory cell unit of the semiconductor device 100.

Each of the memory cells includes a vertical transistor Tr and a capacitor 27. The capacitor 27 is connected to a bit line (or first bit line) B1 including an impurity diffusion layer through the vertical transistor Tr, and the vertical transistor Tr is driven by a word line WL. A second bit line B2 is connected to the bit line (or first bit line) B1 including the impurity diffusion layer through one bit-line switching transistor Tr, which is provided for every four memory cells. When each of word lines W is turned on, accumulation charges emitted from the capacitor 27 may flow to each of the bit lines B1 and B2, and a differential amplifier connected to a terminal of each of the bit lines B1 and B2 determines whether a value is 1 or 0.

### (Method of Fabricating Semiconductor Device)

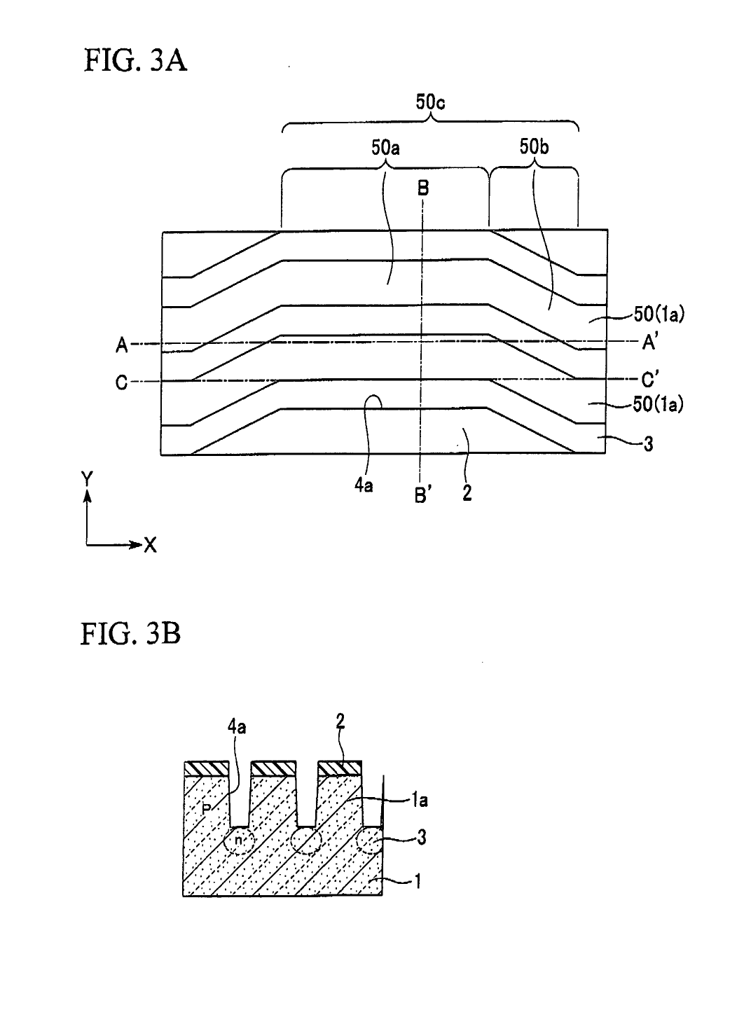

Hereinafter, a method of fabricating a semiconductor device according to the present invention will be described with reference to FIGS. 3 through 17.

Hereinafter, a description of the same components as in the semiconductor device 100 is omitted and simultaneously, the same reference numerals are used to denote the same components in the drawings.

### (Process of Forming Device Isolation Groove and Impurity Diffusion Region)

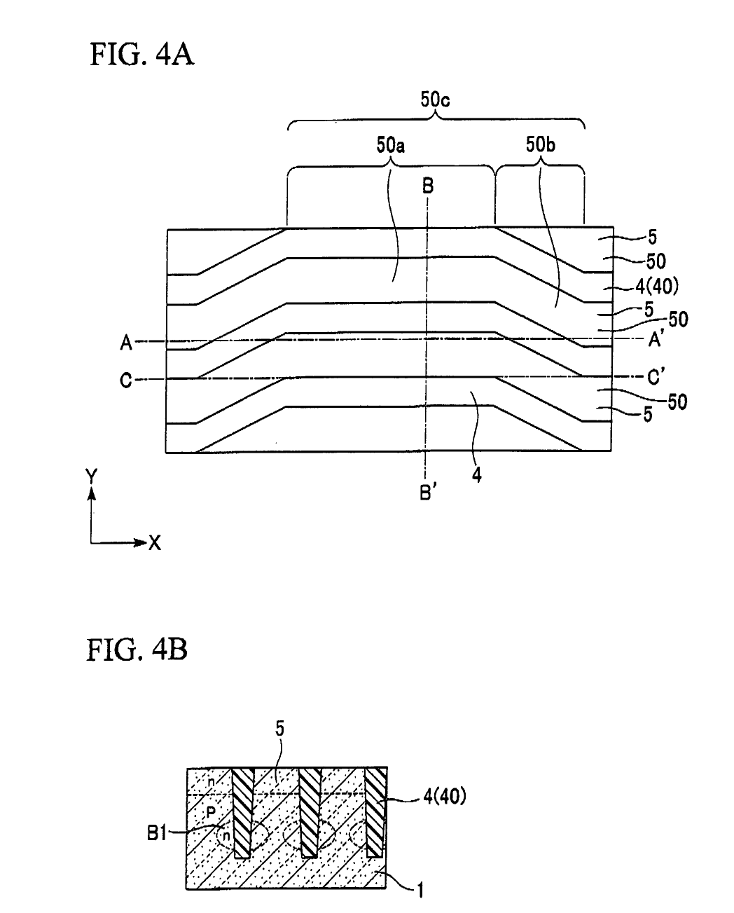

FIG. 3A is a plan view, and FIG. 3B is a cross-sectional view taken along line B-B′ of FIG. 3A. Similarly, FIG. 4A is a plan view, and FIG. 4B is a cross-sectional view taken along line B-B′ of FIG. 4B.

As shown in FIGS. 3A and 3B, initially, a method of fabricating a semiconductor device 100 according to the present invention includes preparing a semiconductor substrate 1 and forming an insulating film 2 on the semiconductor substrate 1. A device isolation region pattern having a plurality of openings extending in an X direction (or first direction) is generally formed in the insulating film 2 using photolithography and dry etching processes. The device isolation region pattern is provided as a snake pattern. A device isolation groove (or first groove unit) 4a constituting the snake pattern is formed in the semiconductor substrate 1 by means of a dry etching process using the patterned insulating film 2 as a mask. Due to the formation of the device isolation groove (or first groove unit) 4a, a semiconductor plate 1a is formed between adjacent device isolation grooves (first groove units) 4a. The semiconductor plate 1a constitutes a device isolation formation region 50. One device formation region 50 includes a combination of a horizontal active region 50a extending in the X direction and an inclined active region 50b inclined with respect to the X direction, as a unit active region 50c. In each of the device formation regions 50, adjacent unit active regions 50c have vertically inverted shapes in a Y direction orthogonal to the X direction, and are repetitively connected and disposed in the X direction. Accordingly, in each of the device isolation formation regions 50, the horizontal active regions 50a are disposed opposite each other at predetermined intervals in the X direction across a line (corresponding to line A-A′) connecting central points of the inclined active regions 50b. Thus, the device formation region 50 has the same snake pattern as the device isolation region pattern. In other words, to form the device formation region 50 having the snake pattern, the device isolation region pattern having the snake pattern is formed. In the present embodiment, it is necessary to form the device formation region 50 having the snake pattern.

Specifically, for example, device isolation grooves are formed in a p-type single-crystalline silicon substrate by an anisotropic etching process using the p-type single-crystalline silicon substrate as the semiconductor substrate 1 and using a silicon nitride film as the insulating film 2. The formed device isolation groove may have, for example, a depth of about 150 nm and a width of about 40 nm.

As shown in FIG. 3B, impurities are implanted into the entire surface of the resultant structure using the insulating film 2 as a mask, thereby forming an impurity diffusion region 3 in a bottom portion of the device isolation groove (or first groove unit) 4a.

For example, arsenic (As) is implanted as impurities at an energy of about 5 KeV to form an n-type diffusion region 3.

### (Process of Forming First Bit Line and Device Isolation Region)

As shown in FIG. 4B, impurities implanted into a bottom unit of the device isolation groove (or first groove unit) 4a are diffused using an annealing process toward the center of the semiconductor plate la to increase the width of the impurity diffusion region 3. As a result, a bit line (or first bit line) B1 including two diffusion layers is formed in a lower portion of the semiconductor plate 1a. Since the first bit line B1 is formed in accordance with the shape of the semiconductor plate 1a having the snake pattern, the first bit line B1 has the same snake pattern as the semiconductor plate 1a.

For example, arsenic (As) is diffused to a distance of about 15 nm using a lamp annealing process, thereby forming the bit line (or first bit line) B1 including the diffusion layers.

As shown in FIG. 4A, the device isolation groove 4a of the semiconductor substrate 1 is further etched by a dry etching process using the insulating film 2 as a mask, and filled with a first insulating film 4, thereby forming an STI device isolation region 40. Due to the formation of the device isolation region 40, a device formation region 50 is formed between the device isolation regions 40 disposed adjacent to each other in the Y direction. One device formation region 50 includes a combination of a horizontal active region 50 extending in the X direction and an inclined active region 50b inclined with respect to the X direction, as a unit active region 50c.

The formation of the STI device isolation region 40 includes etching the device isolation groove of the silicon substrate to a depth of about 250 nm using, for example, a silicon nitride film as a mask, and filling the etched device isolation groove 4a with a silicon nitride film. Thus, as shown in FIG. 4B, the first bit line B1 includes an impurity diffusion layer 3 having one end that contacts the device isolation insulating film 4. From a plan view, two impurity diffusion layers 3 are disposed in one device formation region 50, and contact two device isolation insulating films 4 vertically disposed in the Y direction. While the two impurity diffusion layers 3 are separated from each other in the center of the device formation region 50, the two impurity diffusion layers 3 function as one first bit line B1. Each of the two impurity diffusion layers 3 is a snake pattern.

An impurity diffusion region (or upper impurity diffusion region) 5 is formed in the surface of the semiconductor plate 1a by implanting impurities in the entire surface of the resultant structure.

For example, phosphorus (P) is implanted as impurities to form an n-type diffusion region 5.

### (Process of Forming Groove for Forming Word Line)

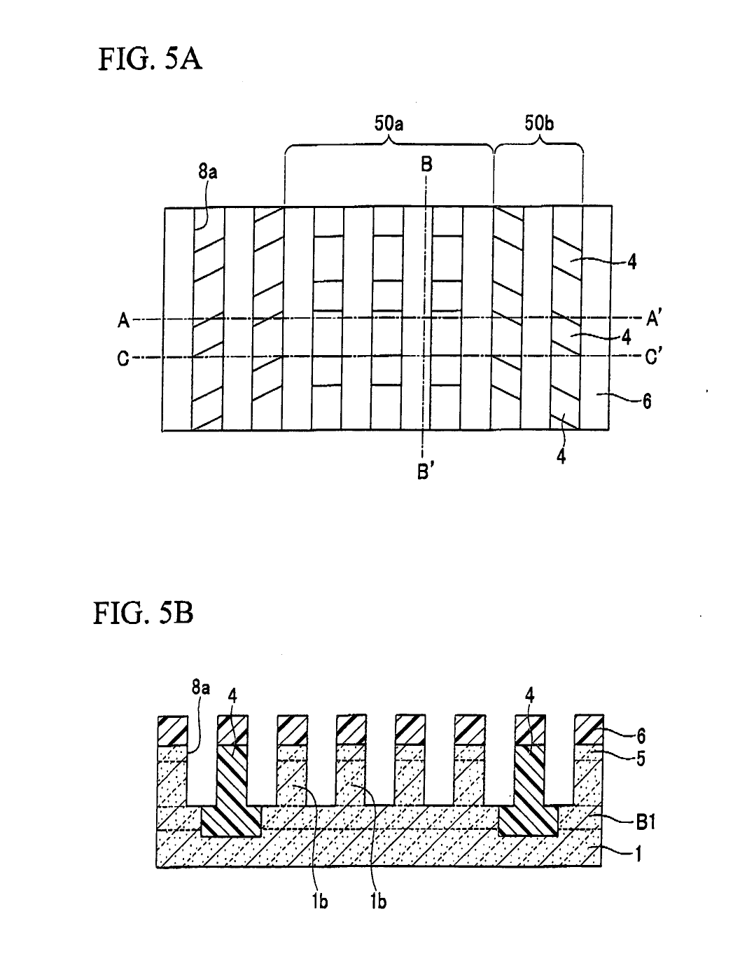

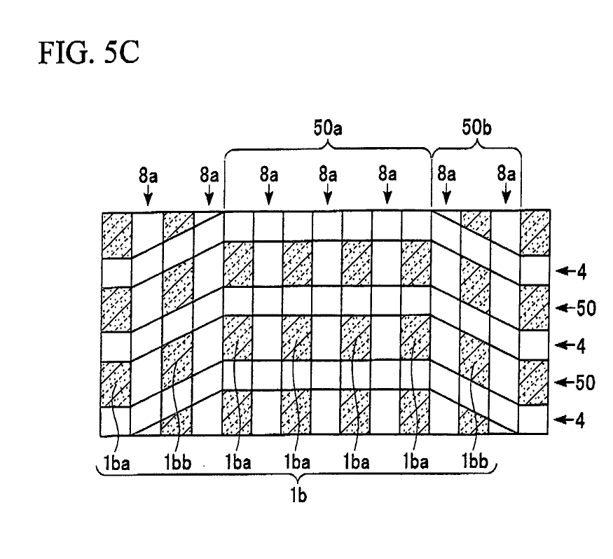

FIGS. 5A and 5C are plan views, and FIG. 5B is a cross-sectional view taken along line A-A′ of FIG. 5A.

As shown in FIGS. 5A and 5B, an insulating film 6 is formed on the entire surface of the resultant structure, and photolithography and dry etching processes are performed on the insulating film 6, thereby forming a groove pattern for forming a word line having a plurality of openings extending in a straight line in the Y direction (or second direction). A groove (or second groove unit) 8a for forming the word line is formed by a dry etching process using the patterned insulating film 6 as a mask. The groove (or second groove unit) 8a communicates with the semiconductor plate 1a and the first insulating film 4 and extends in the Y direction (or second direction. Due to the formation of the groove (or second groove unit) 8a for forming the word line, the semiconductor plate 1a is separated in the X direction (or first direction) to form semiconductor pillars 1b. The groove (or second groove unit) 8a for forming the word line is formed to such a depth as not to penetrate the first bit line B1 in a depthwise direction. Here, when the groove (or second groove unit) 8a for forming the word line is formed to such a depth to penetrate the first bit line, the first bit line B1 extending as the snake pattern is divided into parts and loses its continuity.

For example, a silicon oxide film is formed as the insulating film 6 to a thickness of about 50 nm on the entire surface of the resultant structure, and lithography and dry etching processes are performed to form a mask of the insulating film 6 having a line-and-space pattern with a width of about 40 nm and a space of about 40 nm. Next, the silicon substrate 1 is etched by a dry etching process using the insulating film 6 as a mask so that a groove (or second groove unit) 8a for forming a word line is formed to a depth of about 150 nm from the surface of the silicon substrate 1. FIG. 5C is a transmission view of the insulating film 5 serving as the mask, which shows arrangement of the semiconductor pillars 1b. In one device formation region 50, four semiconductor pillars 1b formed in the horizontal active region 50a become capacitor semiconductor pillars 1ba functioning as switching vertical transistors configured to form an electrical conduction path between a first bit line B1 and a capacitor in a subsequent process. Meanwhile, one semiconductor pillar 1b formed in the inclined active region 50b becomes a bit line semiconductor pillar 1bb functioning as a switching vertical transistor configured to form an electrical conduction path between the first and second bit lines B1 and B2 in a subsequent process.

### (Process of Forming Gate Insulating Film and Buried Word Line)

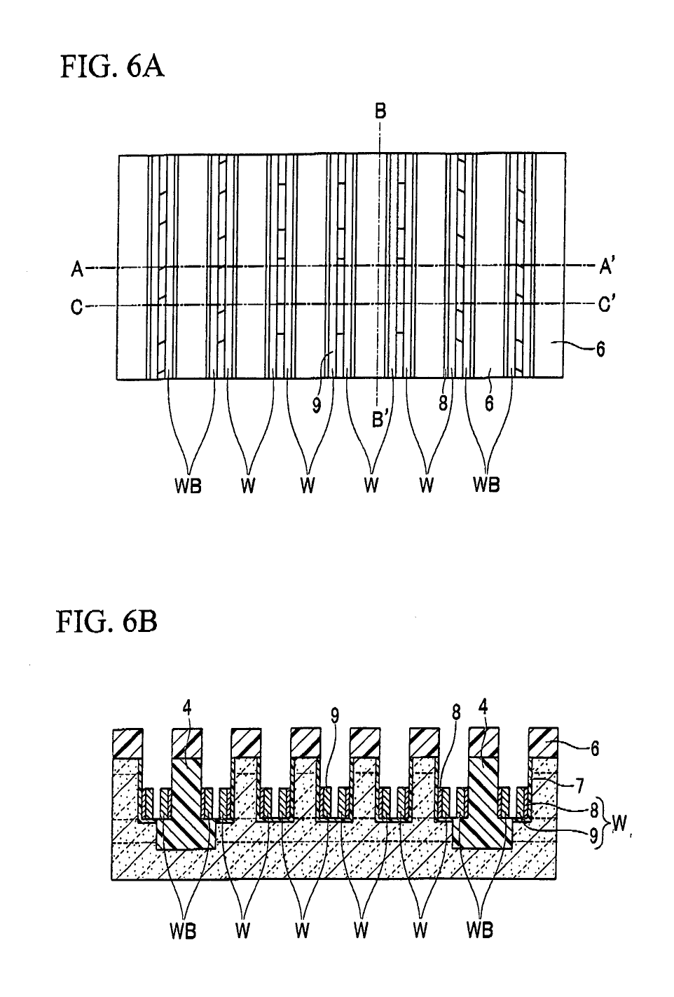

FIG. 6A is a plan view, and FIG. 6B is a cross-sectional view taken along line A-A′ of FIG. 6A.

As shown in FIG. 6B, a gate insulating film (or second insulating film) 7 is formed within the groove (or second groove unit) 8a for forming the word line. Also, as shown in FIGS. 6A and 6B, buried word lines W are formed using the gate oxide film 7 on sidewalls of the groove (or second groove unit) 8a for forming the word line, that is, on lateral surfaces of the semiconductor pillar 1b parallel in the Y direction (or second direction). In the present embodiment, a pair of buried word lines W are formed on the two lateral surfaces of the semiconductor pillar 1b parallel in the Y direction (or second direction) to provide a double gate structure.

For example, the gate oxide film 7 is formed to a thickness of about 5 nm using a thermal oxidation process on lateral and bottom surfaces of the groove (or second groove unit) 8a for forming the word line. Thereafter, a TiN film 8 and a W film 5 are formed to thicknesses of 3 nm and 7 nm, respectively, using a CVD method on the entire surface of the resultant structure, and etched back using a dry etching process. Thus, a buried word line W (or W film 9 and a TiN film 8) is formed as a sidewall type to a height of about 80 nm less than the depth of the groove for forming the word line only on lateral surfaces of the groove for forming the word line.

As a result, the buried word line W is formed in each of capacitor semiconductor pillars 1ba formed in the horizontal active region 50a and serves as a word line of a DRAM. The buried word line W functions as a gate electrode of a switching vertical transistor, which includes a plurality of capacitor semiconductor pillars 1ba disposed in the Y direction. Simultaneously, a buried gate electrode WB is formed in a plurality of bit line semiconductor pillars 1bb formed in the inclined active regions 50b in the Y direction, and used to drive the switching vertical transistor configured to form an electrical conduction path between first and second bit lines.

### (Process of Forming Buried Insulating Film on Buried Word Line)

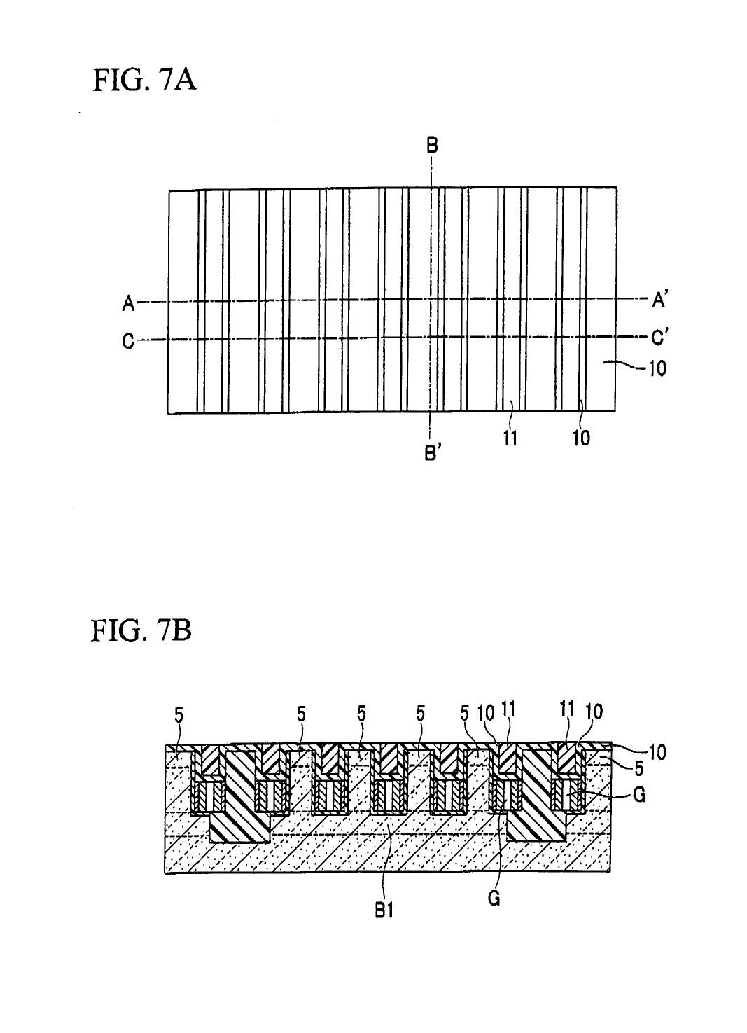

FIG. 7A is a plan view, and FIG. 7B is a cross-sectional view taken along line A-A′ of FIG. 7A.

As shown in FIGS. 7A and 7B, a buried insulating film (or third insulating film) 10 and a buried insulating film 11 are formed on the buried word line W (W film 9 and the TiN film 8).

A silicon oxide film 10 is formed to a thickness of about 5 nm as not to completely fill a groove 8a for forming a word line on the buried word line W (W film 9 and the TiN film 8) using, for example, a low-pressure CVD (LPCVD) technique. Also, a silicon nitride film is formed thereon to a thickness of about 20 nm and etched back using a dry etching process so that a silicon nitride film 11 can be formed to leave a buried silicon nitride film only within the groove 8a for forming the word line. Thus, as shown in FIGS. 7A and 7B, the groove 8a for forming the word line is filled with the silicon oxide film 10 and the silicon nitride film 11, and the silicon oxide film 10 is formed on the entire outer surface of the groove 8a for forming the word line. In this case, since a tetraethyl orthosilicate (TEOS) film having poor gap-fill characteristic is used as the silicon oxide film 10, air gaps G are formed between the buried word lines W and between the buried gate electrodes WB in adjacent semiconductor pillars 1b of the grooves 8a for forming the word lines, and inter-electrode capacitances may be reduced. Thus, a vertical MOS transistor including the upper impurity diffusion region 5 serving as a source, the first bit line B1 serving as a drain, and the gate insulating film 7, the buried word line W, and the capacitor semiconductor pillar 1ba serving as a channel, is formed. The vertical MOS transistor functions as a switching transistor configured to connect the capacitor and the first bit line B1.

### (Process of Forming Opening for Bit Line Contact and Diffusion Layer)

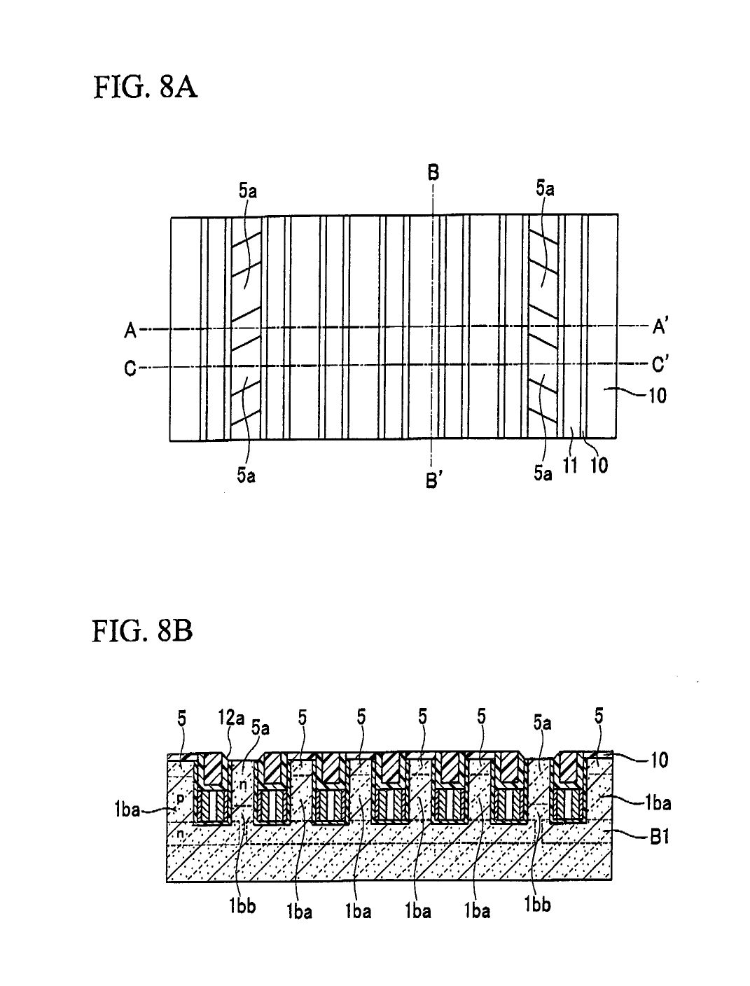

FIG. 8A is a plan view, and FIG. 8B is a cross-sectional view taken along line C-C′ of FIG. 8A.

As shown in FIGS. 8A and 8B, a plurality of openings 12a for second bit line contacts are formed in a straight shape in the buried insulating film 10 in the X direction (or first direction) to correspond to a predetermined number of rows of semiconductor pillars. The plurality of openings 12a for the second bit line contacts bulk-expose surfaces (or first surfaces) of each row of bit line semiconductor pillars 1bb arranged in the Y direction (or second direction). As shown in FIG. 8A, the surfaces (or first surfaces) of the bit line semiconductor pillars 1bb and a portion of the device isolation region 40 are exposed in the bulk-opened openings 12a for the second bit line contacts. A second bit line contacts the exposed surfaces (or first surfaces) of the bit line semiconductor pillars 1bb.

For example, an opening 12a for a bit line contact, which extends in the Y direction (or second direction), is patterned in a straight shape to a width of about 60 nm using a photolithography process, and etched using a dry etching process to form an opening 12 for a bit line contact in the silicon oxide film (third insulating film) 10.

As shown in FIG. 8B, n-type impurities, such as arsenic (As), are implanted into the entire surface of the resultant structure using the buried insulating films 10 and 11 as a mask, thereby forming a new upper impurity diffusion region 5a having a higher conductivity than the impurity diffusion region 5 on the bit line semiconductor pillar 1bb having an exposed surface. The impurity implantation process is effective in reducing the resistance of the bit line contact. Thus, a vertical MOS transistor including the upper impurity diffusion region 5a serving as a source, the first bit line B1 serving as a drain, and the gate insulating film 7, the buried gate electrode WB, and the bit line semiconductor pillar 1bb serving as a channel, is formed. The vertical MOS transistor functions as a switching transistor configured to form an electrical conduction path between the first bit line B1 and the second bit line.

### (Process of Forming Second Bit Line)

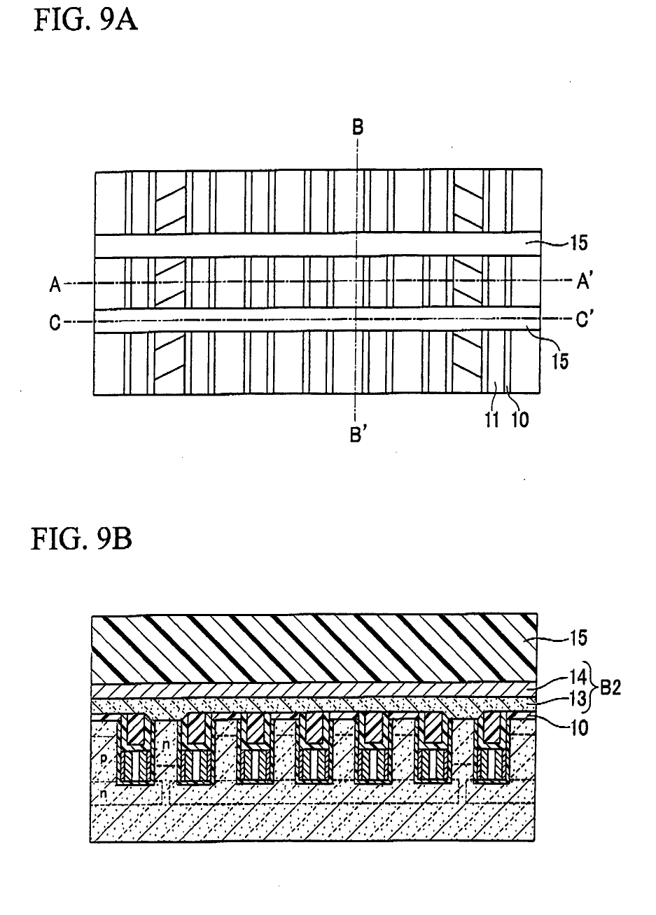

FIG. 9A is a plan view, and FIG. 9B is a cross-sectional view taken along line C-C′ of FIG. 9A.

As shown in FIGS. 9A and 9B, conductive films 13 and 14 are formed on the entire surface of the resultant structure and electrically connected to the exposed surface (or first surface) of the bit line semiconductor pillar 1bb, and an insulating film (fourth insulating film) 15 is further stacked thereon. Next, the insulating film 15 and the conductive films 14 and 13 are sequentially etched using photolithography and dry etching processes, thereby forming a second bit line B2 extending in a straight line in the X direction (or first direction).

For example, a native oxide film is removed from the surface of the bit line semiconductor pillar 1bb, and a polysilicon. (poly-Si) film 13, a W film 14, and a silicon nitride film 15 are formed using a CVD process to thicknesses of about 40 nm, 40 nm, and 150 nm, respectively. The silicon nitride film 15 is etched using lithography and dry etching processes, thereby forming a straight pattern extending in the X direction to a linewidth of about 30 nm and a pitch of about 80 nm. Also, the W film (metal film) 14 and the poly-Si film 13 are sequentially etched by a dry etching process using the straight pattern formed of the silicon nitride film 15 as a mask, thereby forming the second bit line B2 having a poly-metal structure. Since the poly-metal bit line (or second bit line) B2 includes the low-resistance W film (metal film) 14, a low resistance is generally realized to enable high-speed operations of a semiconductor device.

Although not shown, a barrier layer formed of WN or WSi is formed between the poly-Si film 13 and the W film 14.

### (Process of Forming Capacitor Contact Plug)

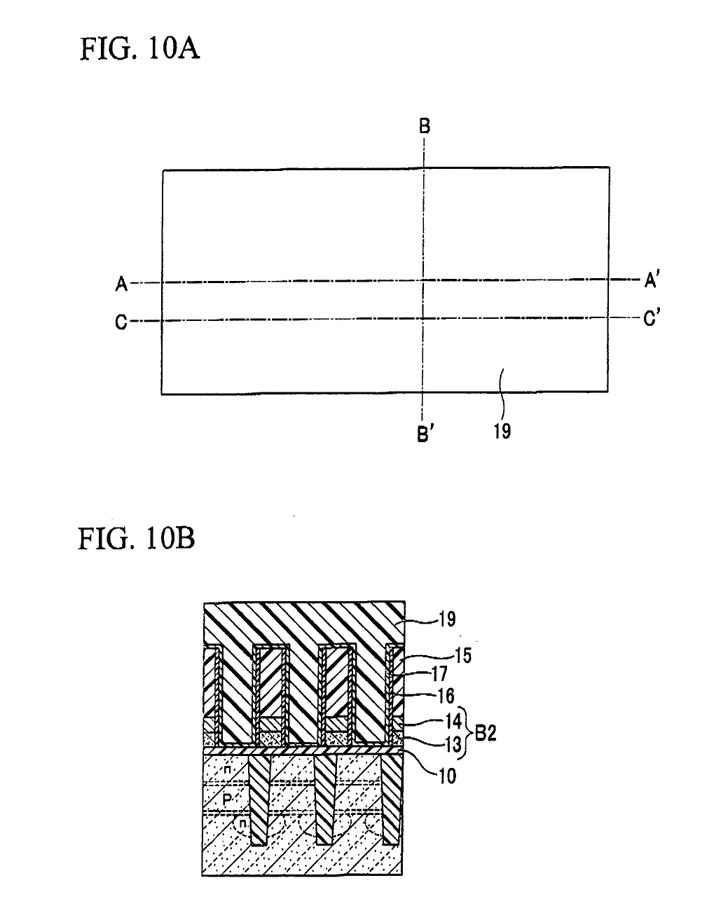

Next, a process of forming a capacitor contact plug will be described with reference to FIGS. 10 through 15.

FIG. 10A is a plan view, and FIG. 10B is a cross-sectional view taken along line B-B′ of FIG. 10A.

As shown in FIGS. 10A and 10B, a sidewall insulating film 16, a liner insulating film 17, and an insulating film (fifth insulating film) 19 are formed.

For example, a silicon nitride film is formed using a CVD process to a thickness of about 5 nm on the entire surface of the resultant structure, and etched back using a dry etching process, thereby forming the sidewall insulating film 16 to cover sidewalls of the second bit line B2. Next, the liner insulating film 17 including a silicon nitride film is formed to a thickness of about 5 nm using a CVD process on the entire surface of the resultant structure not to bury a space between adjacent second bit lines B2. By forming the sidewall insulating film 16 and the liner insulating film 17, the distance between the adjacent second bit line B2 and insulating film 15 is reduced from about 50 nm to 30 nm. Next, the insulating film (fifth insulating film) 19 including a silicon oxide film is formed using a CVD process to a thickness of about 200 nm on the entire surface of the resultant structure. Also, the surface of the insulating film 19 is planarized using a CMP process. As a result, an insulating film (fifth insulating film) 19 is left to a thickness of about 100 nm on the insulating film (fourth insulating film) 15 disposed on the second bit line B2.

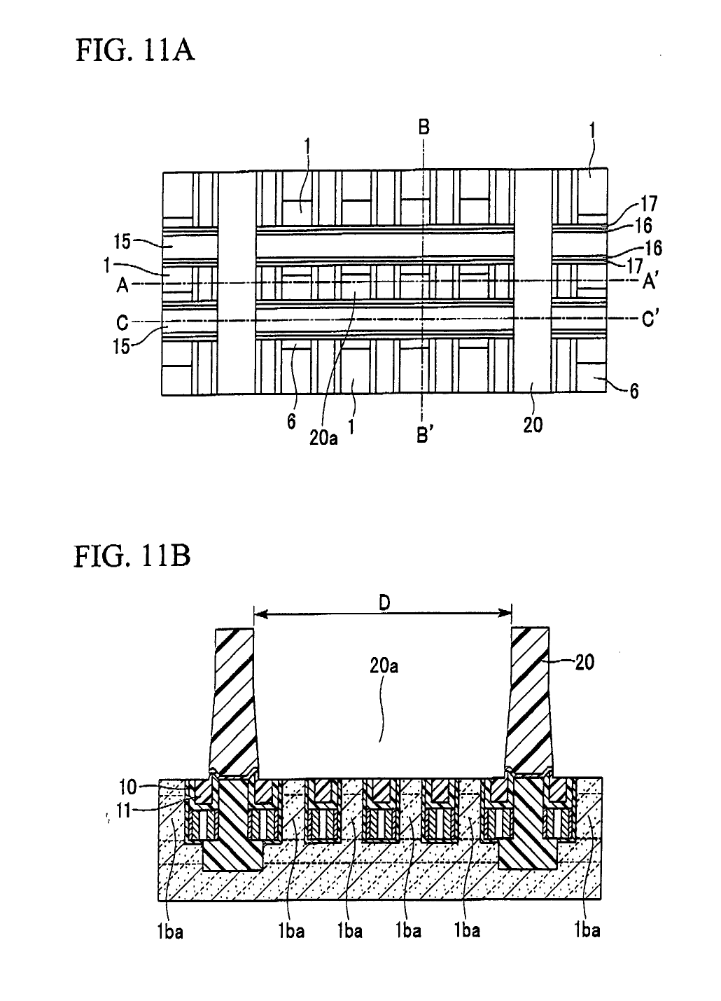

FIG. 11A is a plan view, and FIG. 11B is a cross-sectional view taken along line A-A′ of FIG. 11A.

As shown in FIGS. 11A and 11B, a mask film (not shown) is formed on the insulating film (fifth insulating film) 19 perpendicularly disposed on a plurality of bit line semiconductor pillars 1bb disposed in the Y direction, and extends in a straight line in the Y direction. Next, the insulating film (fifth insulating film) 19 and the buried insulating film (third insulating film) 10 are dry etched using the mask film as a mask. Thus, a subsidiary isolation insulating film 20 including a partitioned silicon oxide film is perpendicularly formed on the plurality of bit line semiconductor pillars 1bb and extends in the Y direction. Simultaneously, the surfaces of the capacitor semiconductor pillars 1ba also are exposed. In the present embodiment, the insulating film (fifth insulating film) 19 includes a silicon oxide film, and the insulating film (fourth insulating film) 15 disposed on the second bit lines B2 includes a silicon nitride film. Accordingly, while the surface of the insulating film (fourth insulating film) 15 is exposed during the dry etching process of forming the subsidiary isolation insulating film 20, the insulating film 15 may be left by adjusting etching conditions.

In the present embodiment, a distance D between adjacent subsidiary isolation insulating films 20 is controlled to be about 350 nm. Also, the surface of the subsidiary isolation insulating film 20 is adjusted to a position about 100 nm higher than the surface of the insulating film (fourth insulating film) 15 formed on the second bit line B2. In the present embodiment, the subsidiary isolation insulating film 20 is formed to open the entire horizontal active region 50a. That is, the subsidiary isolation insulating film 20 is formed to expose the surfaces of all the capacitor semiconductor pillars 1ba formed in the horizontal active region 50a. Furthermore, the subsidiary isolation insulating film 20 constitutes a first partition extending in the Y direction. Also, the second bit line B2 and the insulating film 15 constitute a second partition extending in the X direction. In the second partition, the surface of the insulating film 15 is lower than the surface of the subsidiary isolation insulating film 20. Thus, a concave unit 20a is formed to be partitioned by the subsidiary isolation insulating film 20 in the X direction, and partitioned by the second bit line B2 and the insulating film 15 in the Y direction. The subsidiary isolation insulating film 20 is used to separate a conductive film bulk-formed to form a subsequent capacitive contact plug, in the X direction (or first direction).

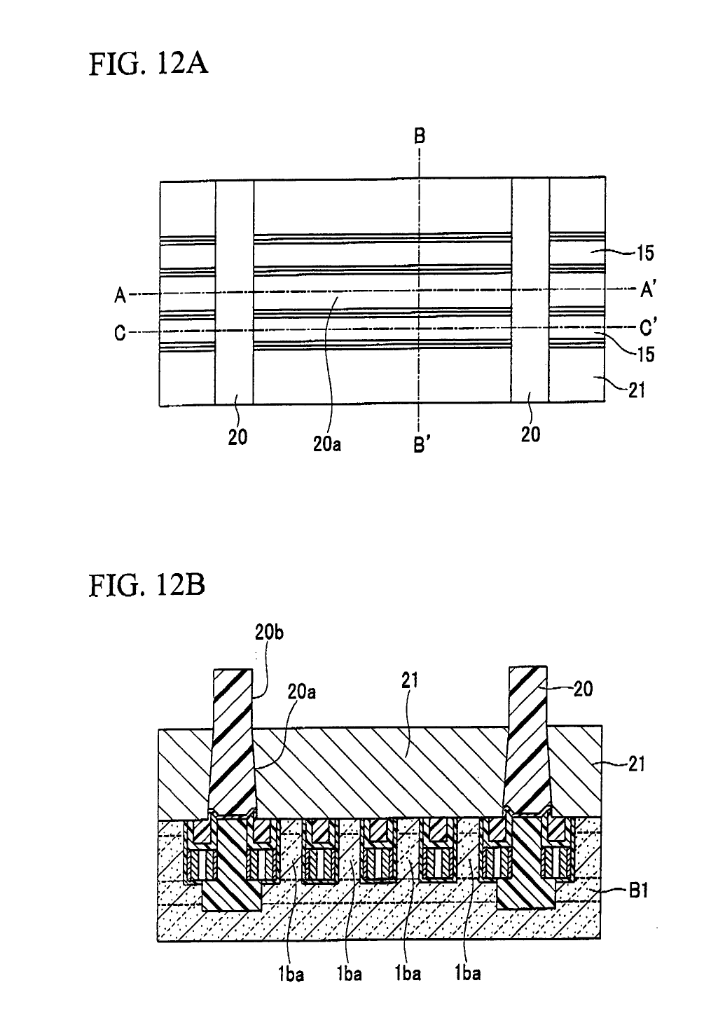

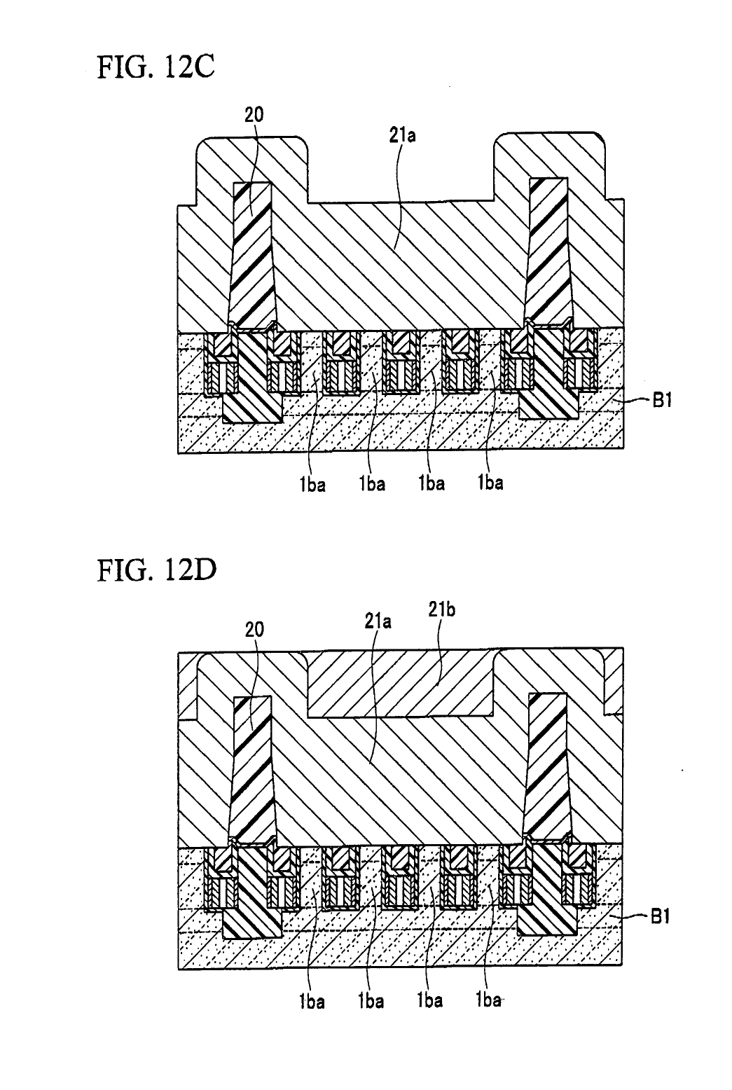

FIG. 12A is a plan view, and FIGS. 12B through 12D are cross-sectional views taken along line A-A′ of FIG. 12A.

As shown in FIGS. 12A and 12B, a conductive film for a capacitive contact plug is formed on the entire surface of the resultant structure to fill the concave unit 20a. Next, the conductive film for the capacitive contact plug is etched back using a dry etching process until the surface of the insulating film (fourth insulating film) 15 is exposed. Thus, the conductive film for the capacitive contact plug is separated by the insulating film (fourth insulating film) 15 in the Y direction (or second direction). Also, the conductive film for the capacitive contact plug is separated in the X direction by a subsidiary isolation insulating film 20 extending in the Y direction. That is, the capacitive contact plug becomes a capacitive contact plug 21 configured to fill the entire concave unit 20a partitioned by the second bit line B2 and the insulating film 15 extending in the X direction and the subsidiary isolation insulating film 20 extending in the Y direction.

For example, as shown in FIG. 12C, a native oxide film is removed from the exposed surface of the capacitor semiconductor pillar 1ba, and a poly-Si film 21a serving as a conductive film for a capacitive contact plug is formed on the entire surface of the resultant structure using a CVD process to a thickness of about 60 nm. Since the distance between the insulating films 15 disposed adjacent to each other in the Y direction is 30 nm as described above, the concave unit 20a is completely filled by forming the poly-Si film 21a to a thickness of about 60 nm. Next, the poly-Si film 21a is etched back using a dry etching process until the surface of the insulating film (fourth insulating film) 15 is exposed. As shown in FIG. 12C, during the etchback process, the poly-Si film 21a is formed in a convex shape on the surface of the isolation insulating film 20 and left as sidewalls on sidewalls of the isolation insulating film 20. To prevent this phenomenon, as shown in FIG. 12D, the surface of the poly-Si film 21a is planarized using a planarization film 21b, such as photoresist, which is formed using a spin coating process, and etched back. Thus, the poly-Si film 21a becomes a capacitance contact plug 21, which is separated by the insulating film (fourth insulating film) 15 in the Y direction (or second direction), and separated by the subsidiary isolation insulating film 20 in the X direction. During this step, a new concave unit 20b having a bottom surface including the surface of the insulating film 15 and the surface of the capacitive contact plug 21 and lateral surfaces including the subsidiary isolation insulating film 20, is formed. Also, since the capacitive contact plug 21 buries the entire concave unit 20a, four capacitor semiconductor pillars 1ba formed in the horizontal active region 50a have a short circuit due to the capacitive contact plug 21. Accordingly, to provide an independent capacitive contact plug corresponding to each of the capacitor semiconductor pillars 1ba, it is necessary to separate the capacitive contact plug 21 once more in the X direction.

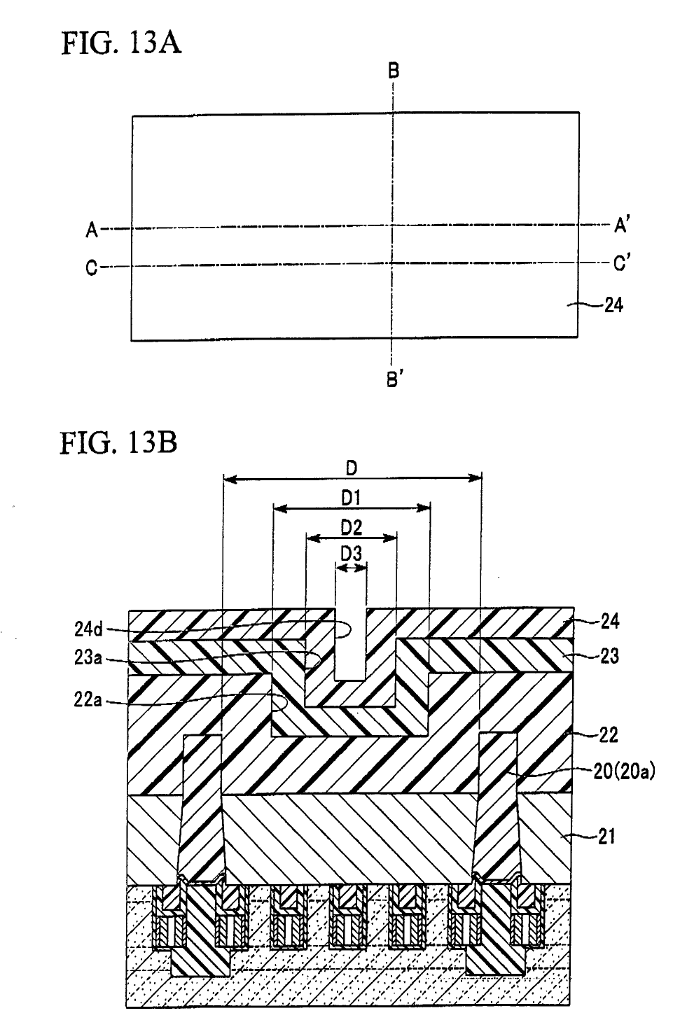

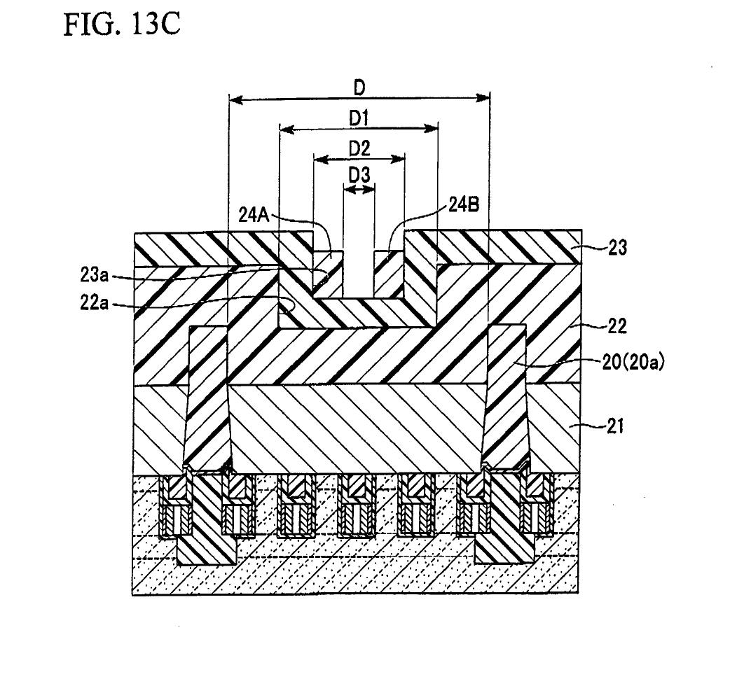

FIG. 13A is a plan view, and FIGS. 13B and 13C are cross-sectional views taken along line A-A′ of FIG. 13A.

As shown in FIGS. 13A and 13B, a stack insulating film (sixth insulating film) is formed on the entire surface of the resultant structure to form a mask used to separate the capacitive contact plug 21, which is separated in the Y direction (second direction) during the process shown in FIG. 12, by the capacitor semiconductor pillars 1ba in the X direction (first direction). To form the mask using the stack insulating film (sixth insulating film), two kinds of insulating films having different etch rates are alternately stacked.

Specifically, for example, as shown in FIGS. 13A and 13B, a first silicon oxide film 22, a silicon nitride film 23, and a second silicon oxide film 24 are sequentially formed using a CVD process to form a tri-layered stack insulating film (sixth insulating film). The first silicon oxide film 22 is formed as a lowermost layer to a thickness of about 50 nm, the silicon nitride film 23 is formed as an intermediate layer to a thickness of about 50 nm, and the second silicon oxide film 24 is formed as an uppermost layer to a thickness of about 50 nm. In the step of FIG. 12B, the subsidiary isolation insulating film 20 protrudes upward from the surface of the capacitive contact plug 21 and the surface of the insulating film 15 to a height of about 100 nm. In the present embodiment, before the stack insulating film, it is necessary to protrude the subsidiary isolation insulating film 20 from the surface of the capacitive contact plug 21 and the surface of the insulating film 15 upward beforehand. Also, the distance D between adjacent subsidiary isolation insulating films 20 becomes about 350 nm. Accordingly, during the formation of the first silicon oxide film 22 serving as the lowermost layer to a thickness of about 50 nm, a first concave unit 22a including the lowermost layer with a width D1 of about 250 nm is formed between the adjacent subsidiary isolation insulating films 20. Thereafter, during the formation of the silicon nitride film 23 serving as the intermediate layer to a thickness of about 50 nm, a second concave unit 23a including the intermediate layer with a width D2 of about 150 nm is formed within the first concave unit 22a including the lowermost layer. Also, during the formation of the second silicon oxide film 24 serving as the uppermost layer to a thickness of about 50 nm, a third concave unit 24d including the uppermost layer with a width D3 of about 50 nm is formed within the second concave unit 23a including the intermediate layer. Since the stack insulating film is formed using a CVD process having the uniformity of a film thickness, the concave unit may have a desired shape and dimension. In addition, since the concave unit may be formed without a lithography process, dimensional changes caused by alignment errors do not occur. Accordingly, the first, second, and third concave units 22a, 23a, and 24d are symmetrically formed with respect to any x-directional central line between adjacent subsidiary isolation insulating films 20.

As shown in FIG. 13C, the second silicon oxide film 24 serving as the uppermost layer is etched back using a dry etching process, thereby forming sidewalls 24A and 24B including the uppermost layer on sidewalls of the second concave unit 23a including the intermediate layer. The sidewalls 24A and 24B are formed in X-directional gaps between the third and second concave units 24d and 23a. Accordingly, the sidewalls 24A and 24B have an X-directional width of about 50 nm. The dry etching process is performed under a condition where the second silicon oxide film 24 has a higher etch rate than (a higher etch selectivity with respect to) the silicon nitride film 23. Thus, a surface of the silicon nitride film 23 serving as the intermediate layer is exposed in a portion except the portion covered with the sidewalls 24A and 24B.

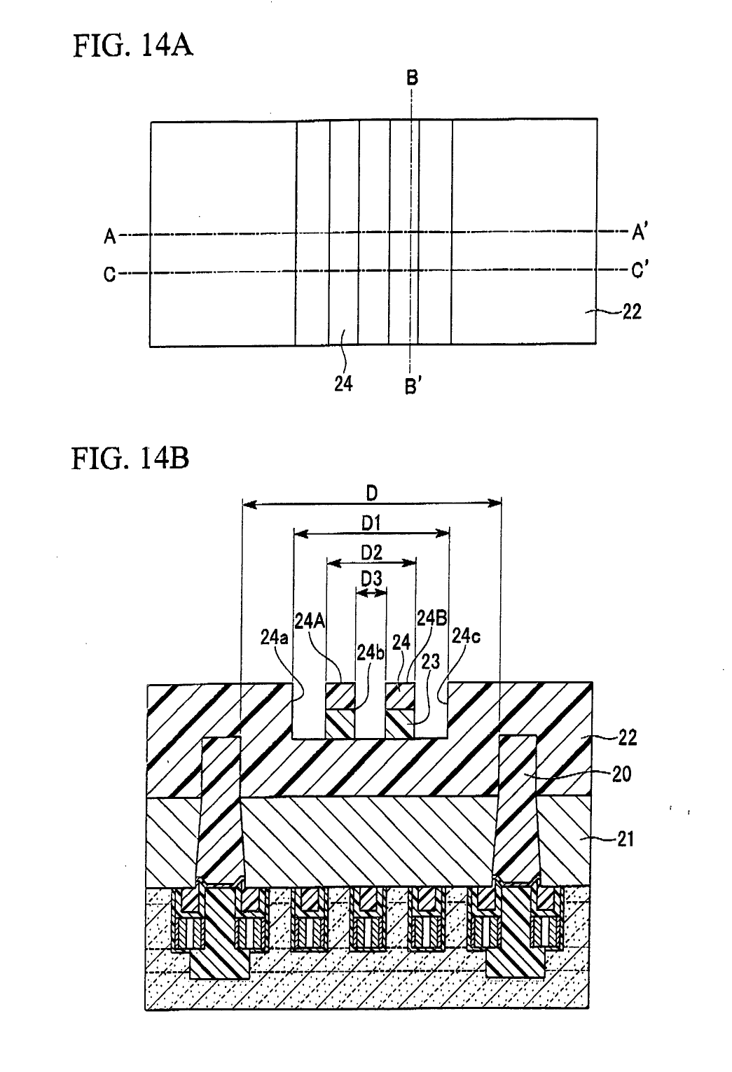

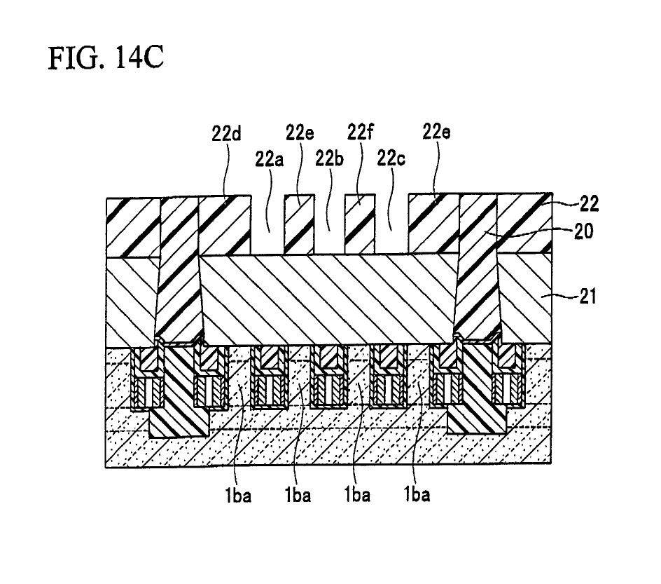

FIG. 14A is a plan view, and FIGS. 14B and 14C are cross-sectional views taken along line A-A′ of FIG. 14A.

As shown in FIGS. 14A and 14B, the intermediate layer 23 having the exposed surface is etched back using a dry etching process. The dry etching process is performed under an etching condition where a silicon nitride film is etched at a higher etch rate than a silicon oxide film. For example, the dry etching process is performed using plasma of a gas mixture containing CH₂F₂, Ar, and O₂. Accordingly, the sidewalls 24A and 24B formed of a silicon oxide film function as masks, and the intermediate layer 23 including a silicon nitride film is left under the sidewalls 24A and 24B. Thus, three grooves 24a, 24b, and 24c are formed within the first concave unit 22a and extend in the Y direction. Each of the three grooves 24a, 24b, and 24c has a width of about 50 nm. Simultaneously, a surface of the first silicon oxide film 22 serving as the lowermost layer is exposed in a portion except the portion where the silicon nitride film 23 is left.

As shown in FIG. 14C, the first silicon oxide film 22 serving as the lowermost layer, which has the exposed surface, is etched back using a dry etching process to transfer three grooves 24a, 24b, and 24c to the first silicon oxide film 22. Thus, grooves 22a, 22b, and 22c are formed and simultaneously, a partial surface of the capacitive contact plug 21 is exposed. The dry etching process is performed under a condition where a silicon oxide film and a silicon nitride film are etched at the same rate. Thus, the intermediate layer 23 including a silicon nitride film used as a portion of the mask is lost during the etch back process. Also, four final mask units 22d, 223, 22f, and 22g are formed using the first silicon oxide film 22 serving as the lowermost layer, which has the three grooves 22a, 22b, and 22c extending in the Y direction.

In the present embodiment, a pattern of the subsidiary isolation insulating film 20 is formed and simultaneously, a concave unit 20b is formed. The pattern of the subsidiary isolation insulating film 20 extends in a straight line in the second direction and protrudes vertically from the surface of the semiconductor substrate. The concave unit 20b is partitioned by the pattern of the subsidiary isolation insulating film 20 in the second direction. The insulating film 22 serving as the lowermost layer is formed on the entire surface of the resultant structure to form the new concave unit 22a extending in the second direction within the concave unit 20b. The insulating film 23 serving as the intermediate layer, which has a different etch rate from the insulating film 22 serving as the lowermost layer, is stacked on the entire surface of the resultant structure to form the new concave unit 23a extending in the second direction within the concave unit 22a. The insulating film 24 serving as the uppermost layer, which has a different etch rate from the insulating film 23 serving as the intermediate layer, is stacked on the entire surface of the resultant structure to form the new concave unit 24d extending in the second direction within the concave unit 23a. The uppermost insulating film 24, the intermediate insulating film 23, and the lowermost insulating film 22 are sequentially repetitively etched back. As a result, grooves extending in the second direction are formed in the lowermost insulating film 22 in number equal to the stacked number of the stack insulating films. Simultaneously, mask units extending in the second direction are formed in a self-aligned manner in a portion except the portion where the grooves are formed, in number equal to the number of the concave units. In the present embodiment, since the stacked number of the stack insulating films is 3, the number of the grooves is 3, the number of the concave units is 4, and the number of the mask units is 4. In the present embodiment, four capacitor semiconductor pillars 1ba are disposed in the semiconductor substrate in the X direction, and three buried word line regions by which the buried insulating films 10 and 11 are exposed are disposed therebetween. The four mask units are disposed in positions corresponding to the four capacitor semiconductor pillars 1ba disposed in the X direction, and the three grooves are disposed in positions corresponding to regions where three buried word lines are formed in the X direction.

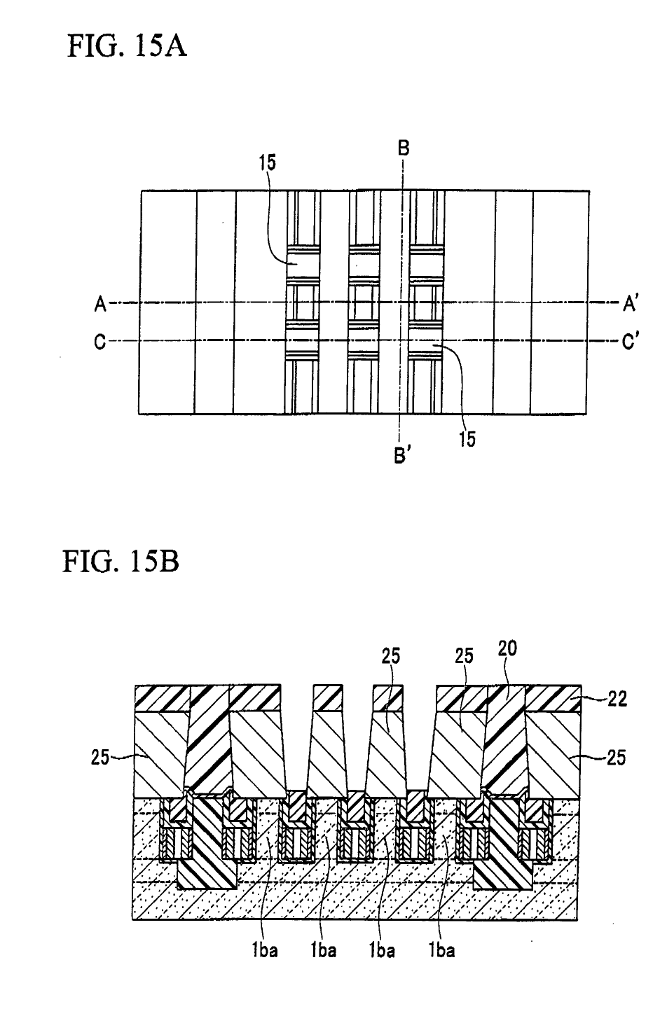

FIG. 15A is a plan view, and FIG. 15B is a cross-sectional view taken along line A-A′ of FIG. 15A.

As shown in FIGS. 15A and 15B, the capacitive contact plug 21 including a poly-Si film is dry etched using, as a mask, the mask units 22d, 22e, 22f, and 22g including the insulating film 22 serving as the lowermost layer formed of a silicon oxide film. Thus, capacitive contact plugs 25 connected to the four capacitor semiconductor pillars 1ba are formed and separated from one another.

### (Process of Forming Capacitor)

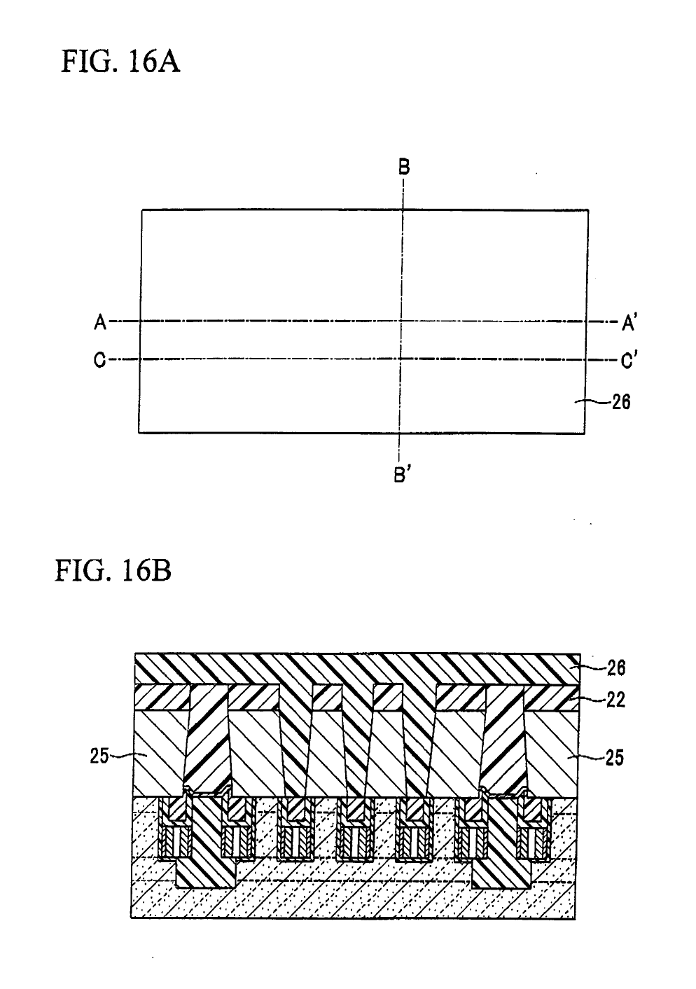

As shown in FIGS. 16A and 16B, an insulating film 26 is formed on the entire surface of the resultant structure.

For example, a silicon nitride film 26 is formed using a CVD process to a thickness of about 30 nm.

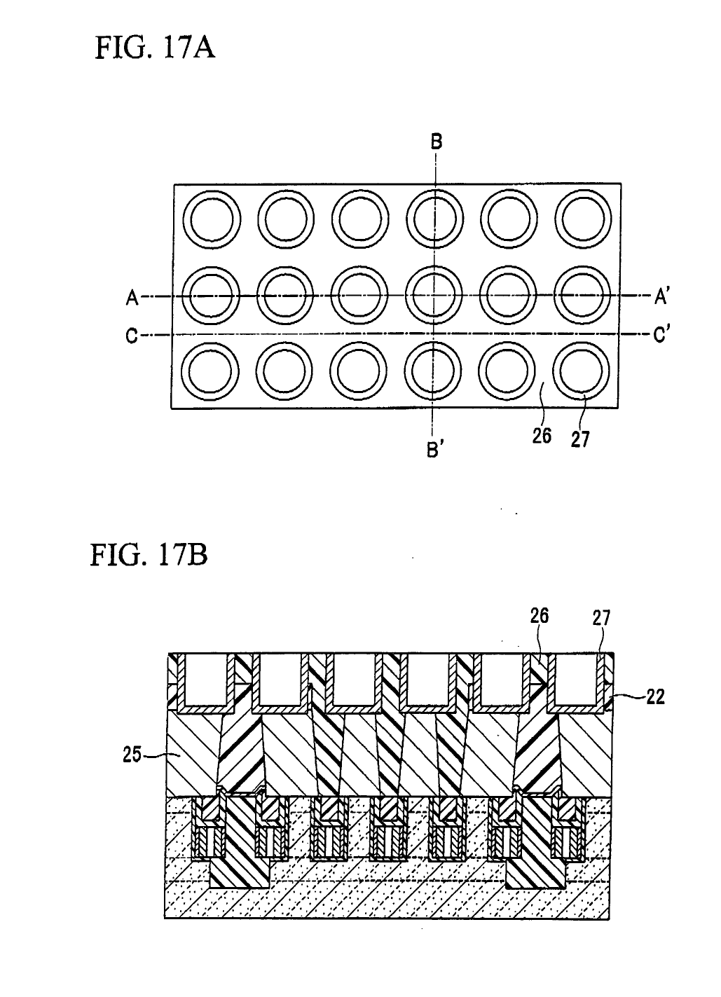

As shown in FIGS. 17A and 17B, a contact hole is formed in the insulating film 26, thereby forming a capacitor (lower electrode of the capacitor) 27 electrically connected to the capacitor contact plug 25.

For example, a hole with a diameter of about 40 nm is patterned using a lithography process, and a contact hole is formed in the silicon nitride film 26 using a dry etching process. Then, a TiN film is formed to a thickness of about 5 nm using a CVD process and separated using a CMP process, thereby forming the capacitor lower electrode. Next, a capacitor and an upper interconnection are formed, thereby completing formation of a DRAM.

As explained thus far, a method of fabricating a semiconductor device according to the present embodiment includes a method of forming capacitive contact plugs, which are connected to the surfaces of the four capacitor semiconductor pillars 1ba, in a self-aligned manner on assumption that four capacitor semiconductor pillars 1ba are disposed in one horizontal active region 50a. Also, the method of forming the capacitive contact plugs in the self-aligned manner includes forming a pattern of the subsidiary isolation insulating film 20 and simultaneously, forming a concave unit 20b. The pattern of the subsidiary isolation insulating film 20 extends in a straight line in the second direction and protrudes vertically from the surface of the semiconductor substrate. The concave unit 20b is partitioned by the pattern of the subsidiary isolation insulating film 20 in the first direction and extends in the second direction. Furthermore, the insulating film 22 serving as the lowermost layer is formed on the entire surface of the resultant structure to form a new concave unit 22a extending in the second direction within the concave unit 20b, The insulating film 23 serving as the intermediate layer, which has a different etch rate from the insulating film 22 serving as the lowermost layer, is stacked on the entire surface of the resultant structure to form a new concave unit 23a extending in the second direction within the concave unit 22a. The insulating film 24 serving as the uppermost layer, which has a different etch rate from the insulating film 23 serving as the intermediate layer, is stacked on the entire surface of the resultant structure to form a new concave unit 24d extending in the second direction within the concave unit 23a. The uppermost insulating film 24, the intermediate insulating film 23, and the lowermost insulating film 22 are sequentially repetitively etched back. As a result, grooves extending in the second direction are formed in the lowermost insulating film 22 in number equal to the stacked number of the stack insulating films. Simultaneously, mask units extending in the second direction are formed in a self-aligned manner in a portion except a portion where the grooves are formed, in number equal to the number of the concave units.

The embodiments of the present invention is not limited to the above-described embodiments but effective even when at least three capacitor semiconductor pillars 1ba are disposed within the horizontal active region 50a. In the present invention, independent contact plugs extending in the second direction may be formed in a self-aligned manner without a lithography process in number equal to the number of concave units. For example, when six capacitor semiconductor pillars 1ba are disposed in one horizontal active region 50a, a pattern of a subsidiary isolation insulating film is formed to partition the horizontal active region 50a in the X direction to form a first concave unit. Thereafter, a first silicon oxide film serving as a lowermost layer is formed to form a second concave unit. A first silicon nitride film serving as a first intermediate layer is formed to form a third concave unit. A second silicon oxide film serving as a second intermediate layer is formed to form a fourth concave unit. A second silicon nitride film serving as a third intermediate layer is formed to form a fifth concave unit. A third silicon oxide film serving as an uppermost layer is formed to form a sixth concave unit. The first through sixth concave units are sequentially formed to form a five-layer stack insulating film. Next, the third silicon oxide film serving as the uppermost layer to the first silicon oxide film serving as the lowermost layer may be sequentially etched back, thereby leaving sixth mask units in the first silicon oxide film serving as the lowermost layer. A dry etching process may be performed using the sixth mask units as a mask so that bulk-formed capacitive contact plugs can be divided into six independent capacitive contact plugs and connected to the sixth capacitor semiconductor pillars 1ba.

Therefore, according to the present invention, when n capacitor semiconductor pillars (n is a natural number greater than 2) are provided, n−1 insulating films having different etch rates may be alternately stacked on a subsidiary isolation insulting film partitioned in the X direction to form n concave units, thereby finally forming n mask units in a lowermost insulating film.

While each of the stacked insulating films is formed to a constant thickness of about 50 nm, an X-directional dimension of the mask units may be changed by adjusting the thickness of each of the stacked insulating films. In addition, while the present embodiment illustrates a capacitive contact plug connected to a capacitor semiconductor pillar as an example, a contact plug formed of poly-Si may be used instead of the semiconductor pillar.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a device formation region comprising a plurality of unit regions arranged in series to each other, each unit region comprising first and second active regions alternately arranged in series to each other, the first active region extending in a first direction, and the second active region extending obliquely to the first direction;
a plurality of first semiconductor pillars arranged in the first direction and in each of the first active regions;
a second semiconductor pillar in each of the second active regions;
a first bit line comprising a first diffusion layer in the device formation region, the first diffusion layer extending under the plurality of first semiconductor pillars and the second semiconductor pillar, the first bit line connecting the plurality of first semiconductor pillars and the second semiconductor pillar; and
a second bit line electrically connected to the second semiconductor pillar.

2. The semiconductor device according to claim 1, further comprising:
a plurality of first insulating layers disposed over the plurality of first semiconductor pillars, the plurality of first insulating layers insulating the second bit line from the plurality of first semiconductor pillars.

3. The semiconductor device according to claim 2, further comprising:
a plurality of second diffusion regions on tops of the plurality of first semiconductor pillars and the second semiconductor pillar, and
wherein the second bit line is electrically connected through the second diffusion region to the second semiconductor pillar.

4. The semiconductor device according to claim 3, wherein the second bit line is in contact with the second diffusion region disposed on the top of the second semiconductor pillar.

5. The semiconductor device according to claim 4, wherein the second bit line extends in the first direction.

6. The semiconductor device according to claim 3, further comprising:
a plurality of second insulating films on side surfaces of the plurality of first semiconductor pillars and a side surface of the second semiconductor pillar; and
a plurality of word lines on the plurality of second insulating films.

7. The semiconductor device according to claim 6, wherein the plurality of word lines extend in a second direction substantially perpendicular to the first direction.

8. The semiconductor device according to claim 6, wherein the second bit line is lower in resistivity than the first bit line.

9. The semiconductor device according to claim 8, wherein the first bit line comprises a pair of first and second bit line portions which are disposed separately in the second direction.

10. The semiconductor device according to claim 9, wherein each of the word lines comprises a pair of first and second word line portions which are disposed separately in the first direction.

11. The semiconductor device according to claim 8, wherein the first bit line comprises a metal layer.

12. The semiconductor device according to claim 3, further comprising:
a plurality of contact plugs electrically connected to the plurality of second diffusion regions; and
a plurality of capacitors electrically connected to the plurality of contact plugs.

13. The semiconductor device according to claim 1, wherein the device formation region is symmetrical with reference to a center axis which extends in the first direction, the center axis runs on center points of the second active regions.

14. A semiconductor device comprising:
a semiconductor substrate including a plurality of device formation regions defined by a plurality of device isolation grooves, each device formation region comprising a plurality of unit regions, each unit region comprising first and second active regions alternately arranged in series to each other, the first active region extending in the first direction, and the second active region extending obliquely to the first direction;
a plurality of first semiconductor pillars arranged in the first direction and in each of the first active regions;
a plurality of second semiconductor pillars, each of which is arranged in each of the second active regions;
a plurality of first bit lines comprising first diffusion layers in the device formation regions, the first diffusion layers extending under the plurality of first semiconductor pillars and the second semiconductor pillars, each of the first bit lines connecting the plurality of first semiconductor pillars and the second semiconductor pillars in each of the device formation regions;
a plurality of second diffusion regions on tops of the plurality of first semiconductor pillars and the second semiconductor pillars;
a plurality of second bit lines electrically connected to the second semiconductor pillars, each of the second bit lines being electrically connected through the plurality of second diffusion regions to the second semiconductor pillars;
a plurality of second bit lines electrically connected to the second semiconductor pillars;
a plurality of first insulating layers disposed over the plurality of first semiconductor pillars, the plurality of first insulating layers insulating the second bit lines from the plurality of first semiconductor pillars;
a plurality of second insulating films on side surfaces of the plurality of first semiconductor pillars and a side surface of the second semiconductor pillar; and
a plurality of word lines on the plurality of second insulating films.

15. The semiconductor device according to claim 14, wherein the first bit line comprises a pair of first and second bit line portions which are disposed separately in the second direction, and each of the word lines comprises a pair of first and second word line portions which are disposed separately in the first direction.

16. The semiconductor device according to claim 14, further comprising:
a plurality of contact plugs electrically connected to the plurality of second diffusion regions; and
a plurality of capacitors electrically connected to the plurality of contact plugs.

17. A semiconductor device comprising:
a device formation region comprising plural pairs of first and second active regions alternately arranged in series to each other;
a plurality of first semiconductor pillars arranged in the first direction and in each of the first active regions;
a second semiconductor pillar in each of the second active regions;
a first bit line comprising a first diffusion layer in the device formation region, the first diffusion layer extending under the plurality of first semiconductor pillars and the second semiconductor pillar, the first bit line connecting the plurality of first semiconductor pillars and the second semiconductor pillar;
a second bit line electrically connected to the second semiconductor pillar; and
a plurality of first insulating layers disposed over the plurality of first semiconductor pillars, the plurality of first insulating layers insulating the second bit line from the plurality of first semiconductor pillars.

18. The semiconductor device according to claim 17, wherein the first active region extends in the first direction and the second active region extends obliquely to the first direction.

19. The semiconductor device according to claim 18, further comprising:
a plurality of second diffusion regions on tops of the plurality of first semiconductor pillars and the second semiconductor pillar, and
wherein the second bit line is electrically connected through the second diffusion region to the second semiconductor pillar.

20. The semiconductor device according to claim 18, further comprising:
a plurality of second insulating films on side surfaces of the plurality of first semiconductor pillars and a side surface of the second semiconductor pillar; and
a plurality of word lines on the plurality of second insulating films,
wherein the first bit line comprises a pair of first and second bit line portions which are disposed separately in a second direction substantially perpendicular to the first direction, and each of the word lines comprises a pair of first and second word line portions which are disposed separately in the first direction.
